(19) United States
(12) Patent Application Publication
(10) Pub. No.: US 2025/0071987 A1
(43) Pub. Date: Feb. 27, 2025

(54) MICROELECTRONIC DEVICES INCLUDING VERTICAL FLAT CELL MEMORY CELL STRUCTURES, AND RELATED MEMORY DEVICES AND ELECTRONIC SYSTEMS

(71) Applicant: Micron Technology, Inc., Boise, ID (US)

(72) Inventor: Yoshiaki Fukuzumi, Tokyo (JP)

(21) Appl. No.: 18/760,750

(22) Filed: Jul. 1, 2024

Related U.S. Application Data
(60) Provisional application No. 63/578,101, filed on Aug. 22, 2023.

(51) Int. Cl. H10B 41/27; H10B 41/35

(52) U.S. Cl. CPC H10B 41/27; H10B 41/35

(57) ABSTRACT

A method of forming a microelectronic device includes forming a top dielectric material over a preliminary stack structure, forming a first slot, partially defined by sidewalls, through the top dielectric material, the preliminary stack structure, and a base structure, forming a first mask material over the sidewalls, forming a trim material over the first mask material, removing portions of the trim material, removing portions of at least the first mask material to form a mask material edge, forming a preliminary separator structure at the mask material edge, and forming a vertical memory string structure. The preliminary stack structure includes tiers having a first material and an insulative material. The vertical memory string structure is horizontally adjacent to the preliminary separator structure. Related microelectronic devices, memory devices, and electronic devices are also disclosed.

### CROSS-REFERENCE TO RELATED APPLICATION

This application claims the benefit under 35 U.S.C. § 119 (c) of U.S. Provisional Patent Application Ser. No. 63/578,101, filed Aug. 22, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices including vertical flat cell memory cells, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often seek to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes strings of memory cells vertically extending through one or more stack structures including tiers of conductive material and insulative material. Each string of memory cells may include at least one select device coupled thereto. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Vertical memory array architectures generally include electrical connections between the conductive material of a tier of the stack structure(s) of the memory device and control logic devices (e.g., string drivers) so that the memory cells of the vertical memory array can be uniquely selected for writing, reading, or erasing operations.

Unfortunately, as feature packing densities have increased and margins for formation errors have decreased, conventional fabrication methods and resulting structural configurations have resulted in undesirable defects that can diminish desired memory device performance, reliability, and durability.

### BRIEF DESCRIPTION OF THE DRAWINGS

FIG. 1 is a simplified, partial top-down view of a microelectronic device structure at a processing stage of a method of forming a microelectronic device, in accordance with embodiments of the disclosure.

FIGS. 2A through 2T are simplified, perspective, partial cutaway views of a portion of the microelectronic device structure shown in FIG. 1 at different processing stages of the method of forming the microelectronic device.

FIG. 2U is a simplified, partial top-down view of the microelectronic device structure following the processing stage of FIG. 2T.

FIG. 3 is a schematic block diagram illustrating an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. The description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one of the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “over,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Moreover, if a material is formed to cover a surface (e.g., a substantially vertical sidewall of a structure), the material may be referred to as being formed “over” the surface even though the material may not be spatially above the covered surface. Likewise, the surface may be referred to as being “under” the formed material. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the terms “hole” and “slot” mean and include a volume extending through at least one structure or at least one material, leaving a void (e.g., gap) in that at least one structure or at least one material, or a volume extending between structures or materials, leaving a gap between the structures or materials. Unless otherwise described, a “hole” and/or “slot” is not necessarily empty of material. That is, a “hole” and/or “slot” is not necessarily void space. A “hole” and/or “slot” formed in or between structures or materials may comprise structure(s) or material(s) other than that in or between which the hole or slot is formed. And, structure(s) or material(s) “exposed” within a “hole” and/or “slot” is (are) not necessarily in contact with an atmosphere or nonsolid environment. Structure(s) or material(s) “exposed” within a “hole” and/or “slot” may be adjacent or in contact with other structure(s) or material(s) that is (are) disposed within the “hole” and/or “slot.”

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, “sacrificial material” means and includes one material that may be selectively removed relative to one or more other materials (e.g., one or more insulative materials). The sacrificial material may be selectively etchable relative to the one or more other materials during common (e.g., collective, mutual) exposure to a first etchant; and the one or more other materials may be selectively etchable to the sacrificial material during common exposure to a second, different etchant. As used herein, a material is “selectively etchable” relative to another material if the material exhibits an etch rate that is at least about five times (5×) greater than the etch rate of another material, such as about ten times (10×) greater, about twenty times (20×) greater, or about forty times (40×) greater. By way of non-limiting example, depending on the material composition of the one or more other materials, the sacrificial material may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}), and at least one semiconductive material (e.g., polycrystalline silicon). The sacrificial material may, for example, be selectively etchable relative to the one or more other materials during common exposure to a wet etchant comprising phosphoric acid (H₃PO₄). In addition, a “sacrificial structure” means and includes a structure formed of and including sacrificial material.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}AS_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

As used herein, the term “pitch” refers to a distance between identical points in two adjacent (e.g., neighboring) features of a repeating pattern.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

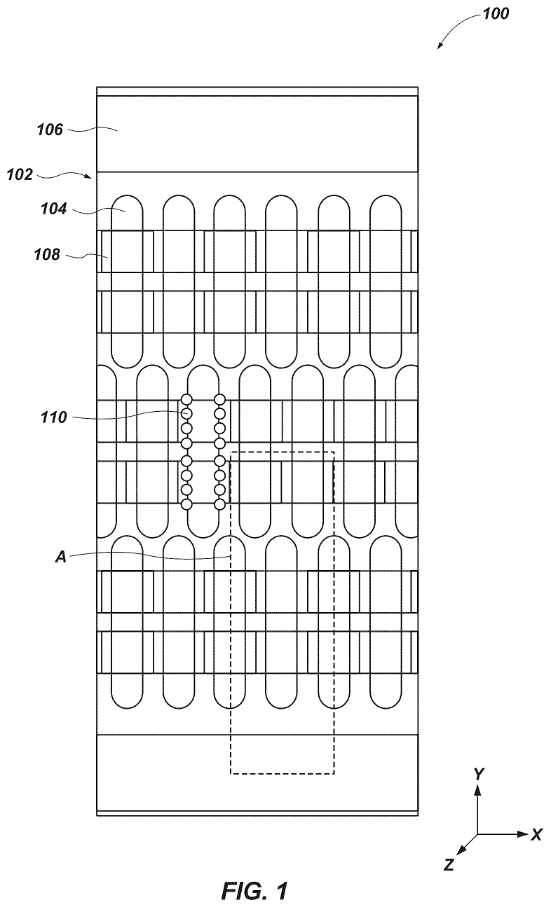

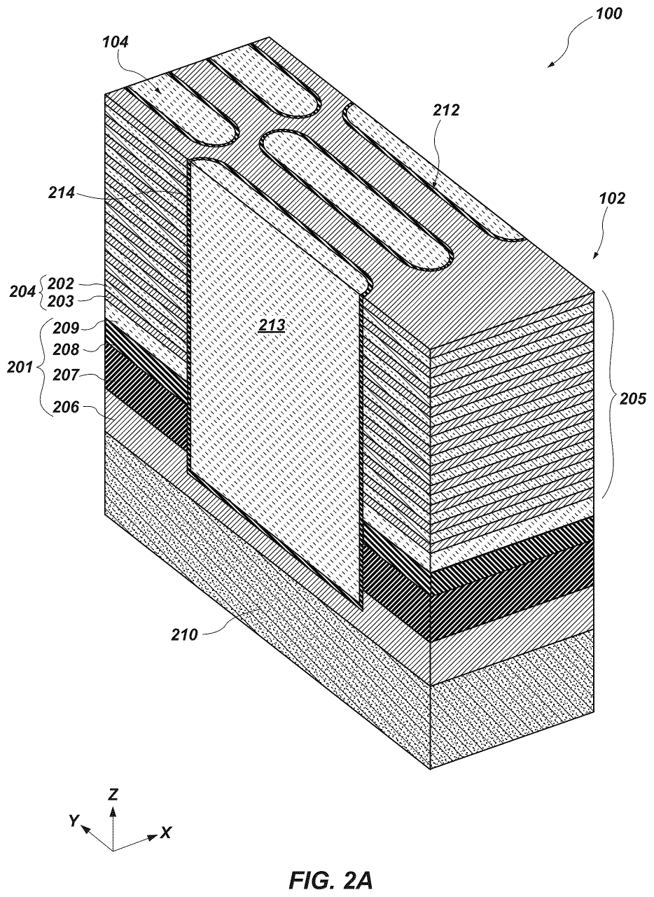

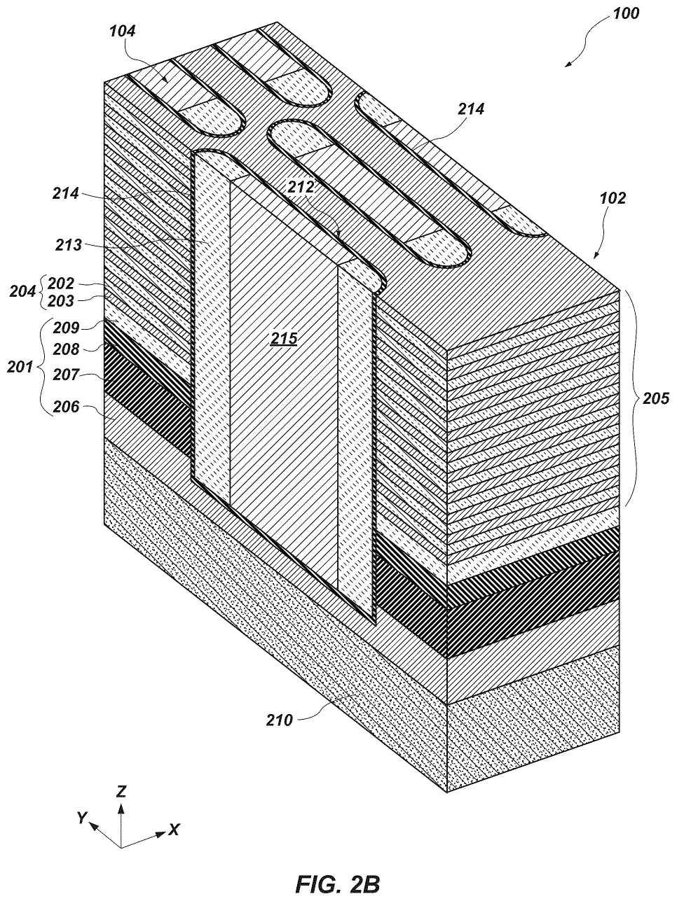

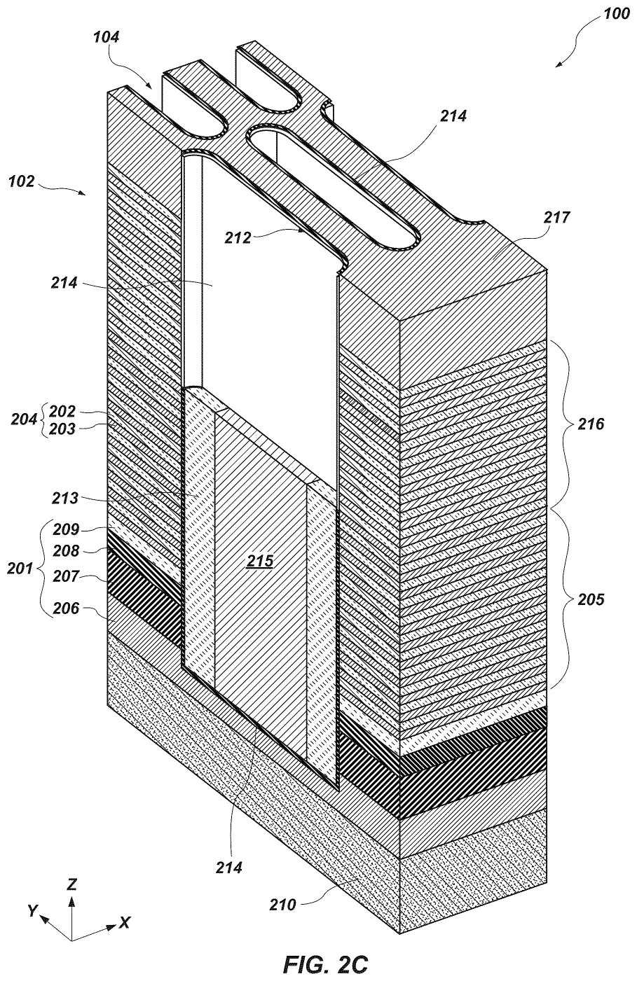

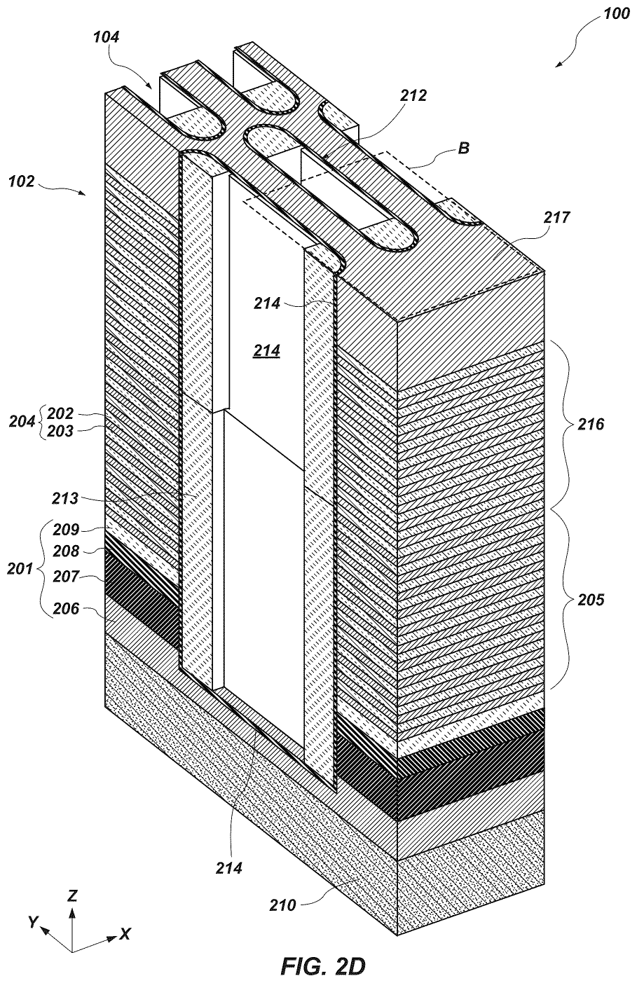

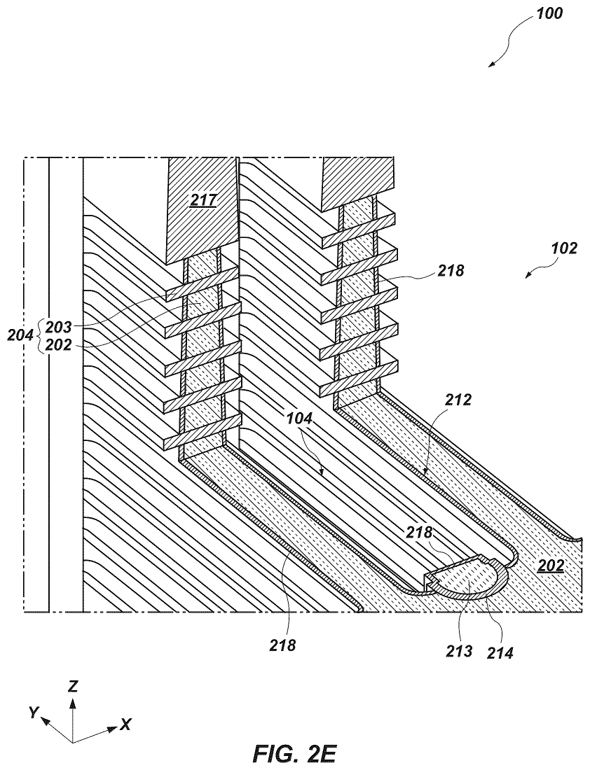

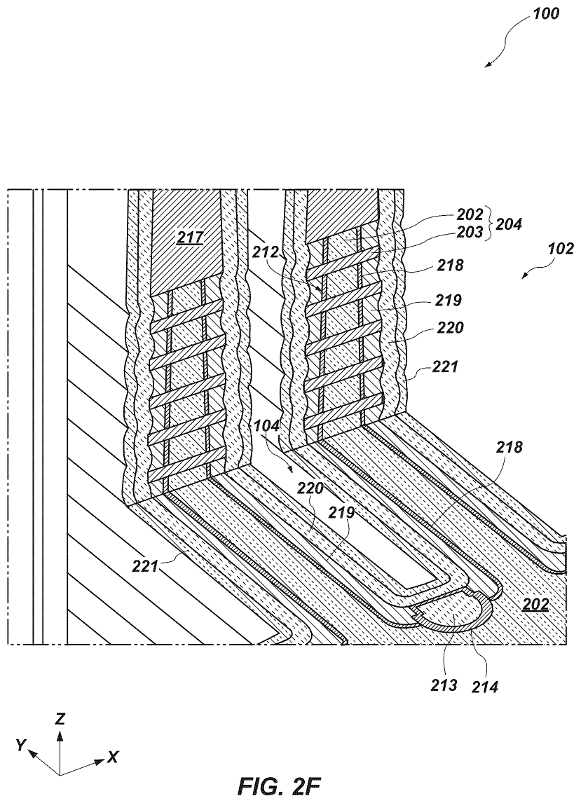

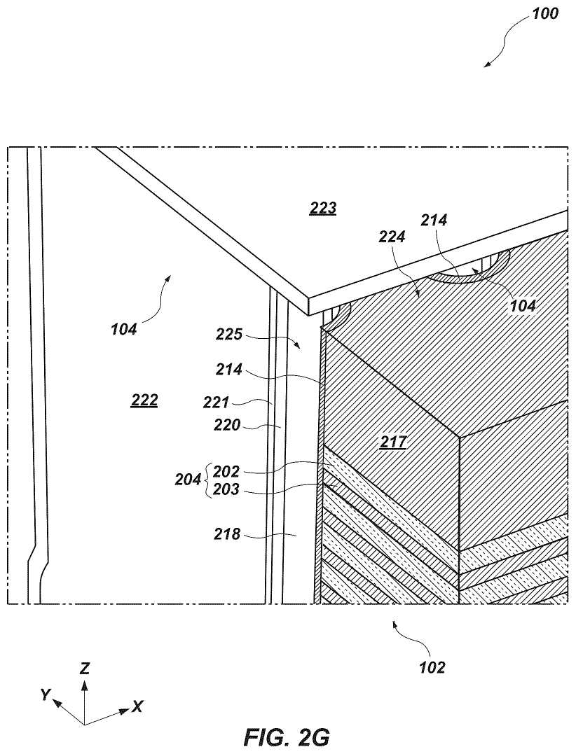

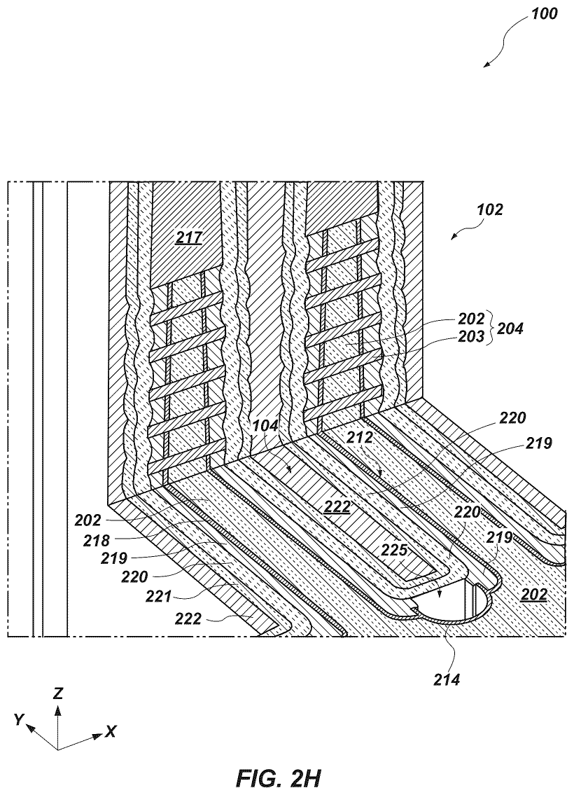

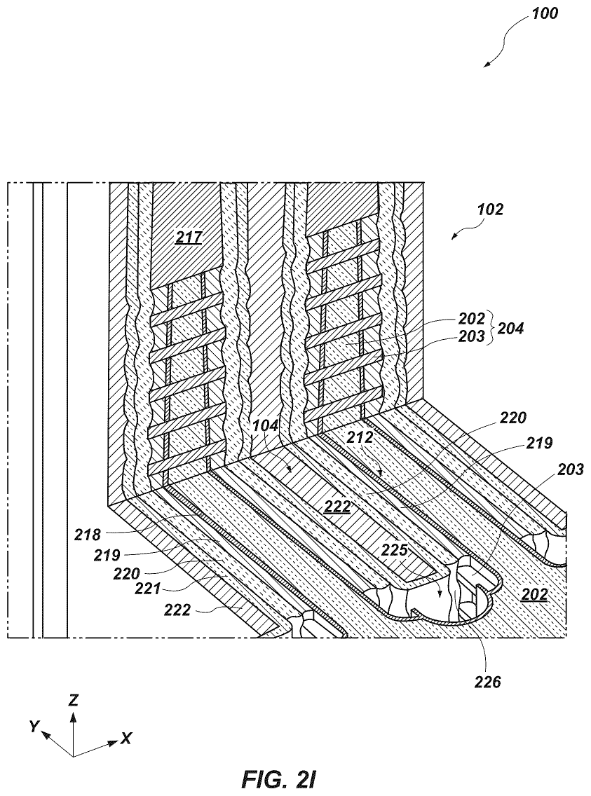

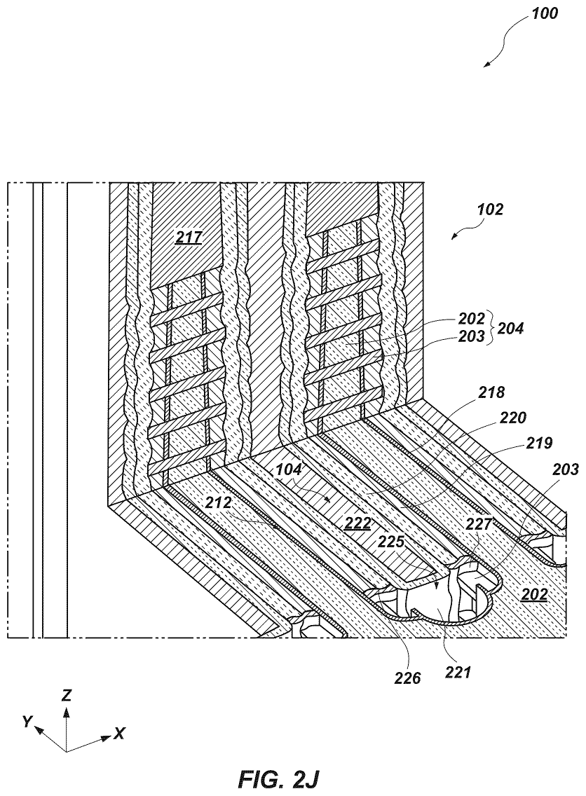

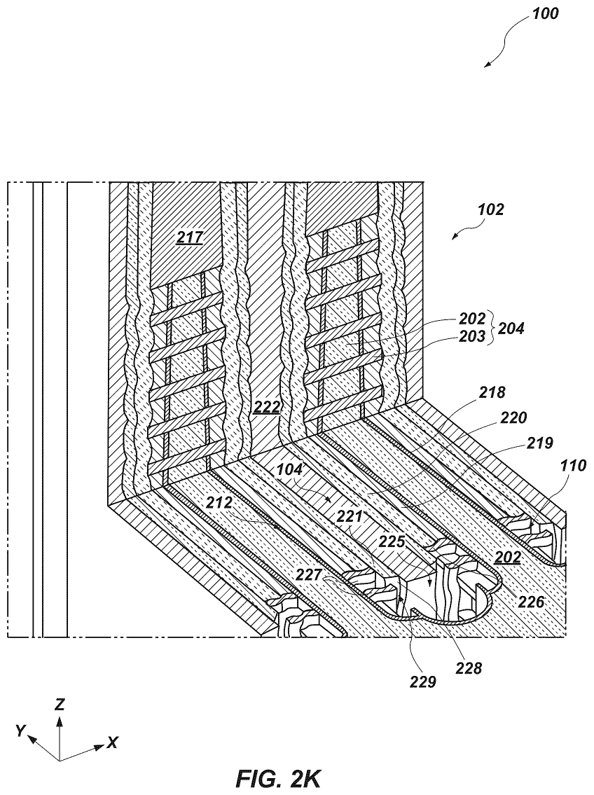

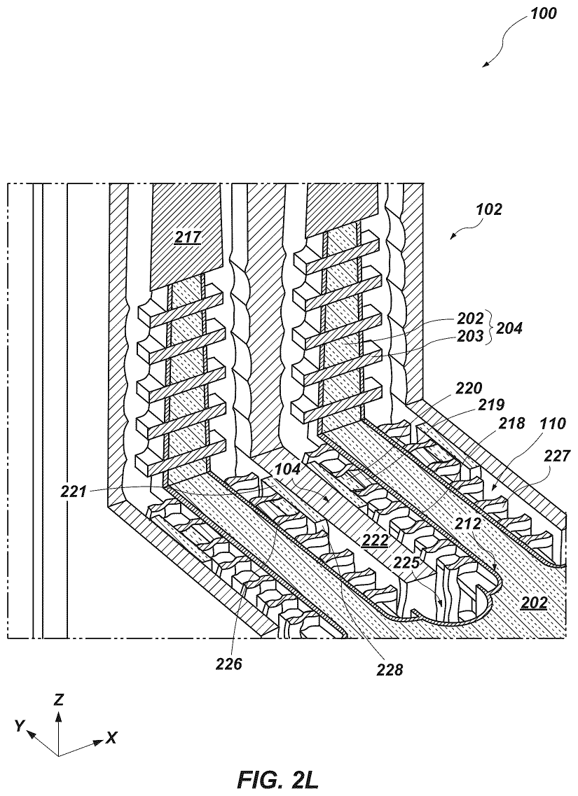

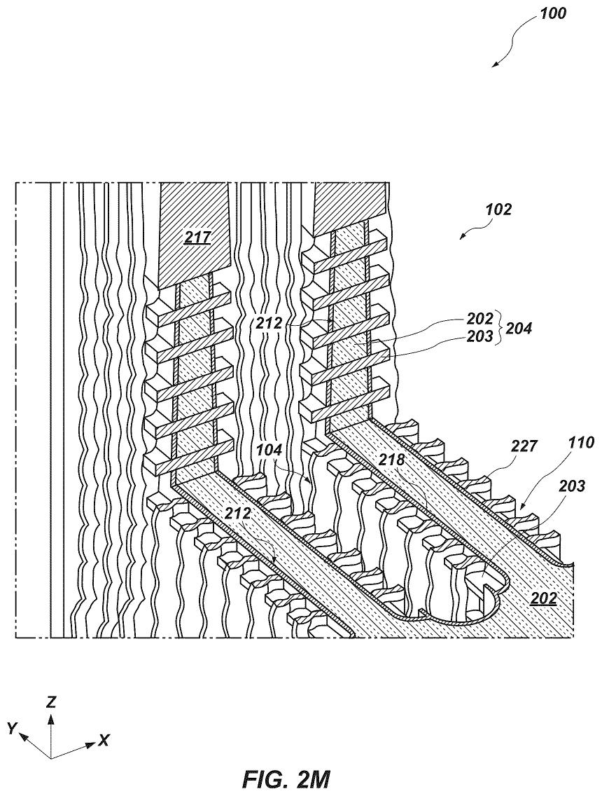

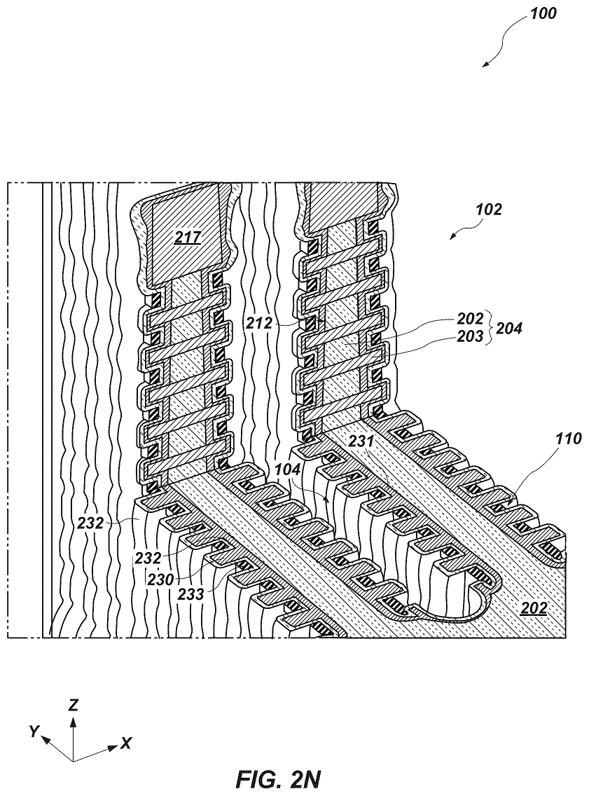

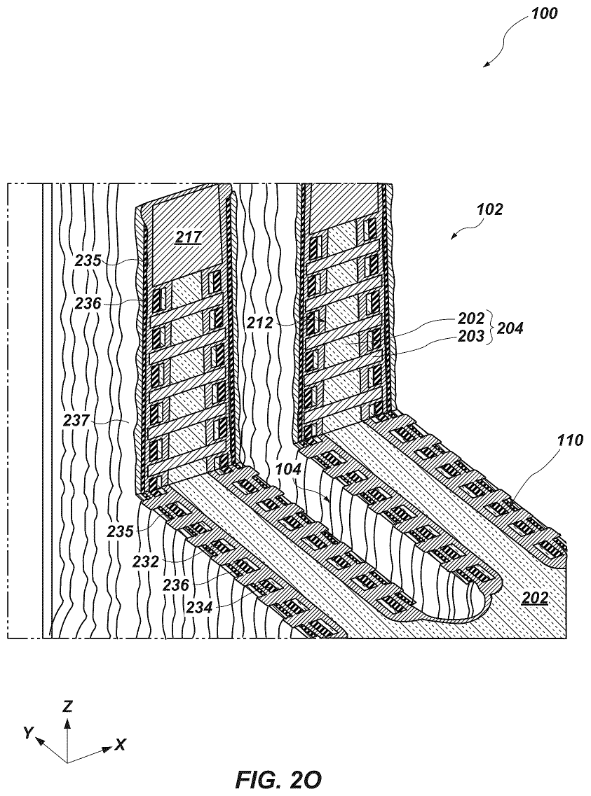

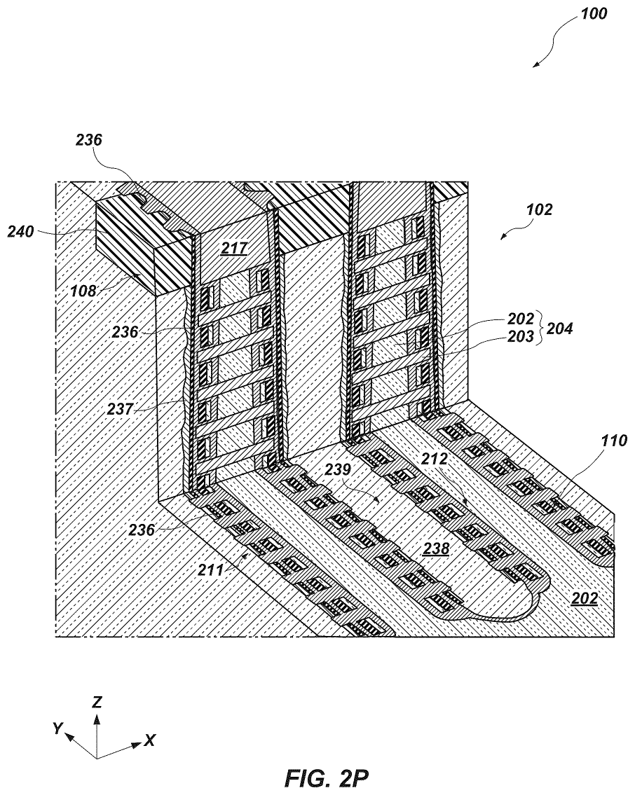

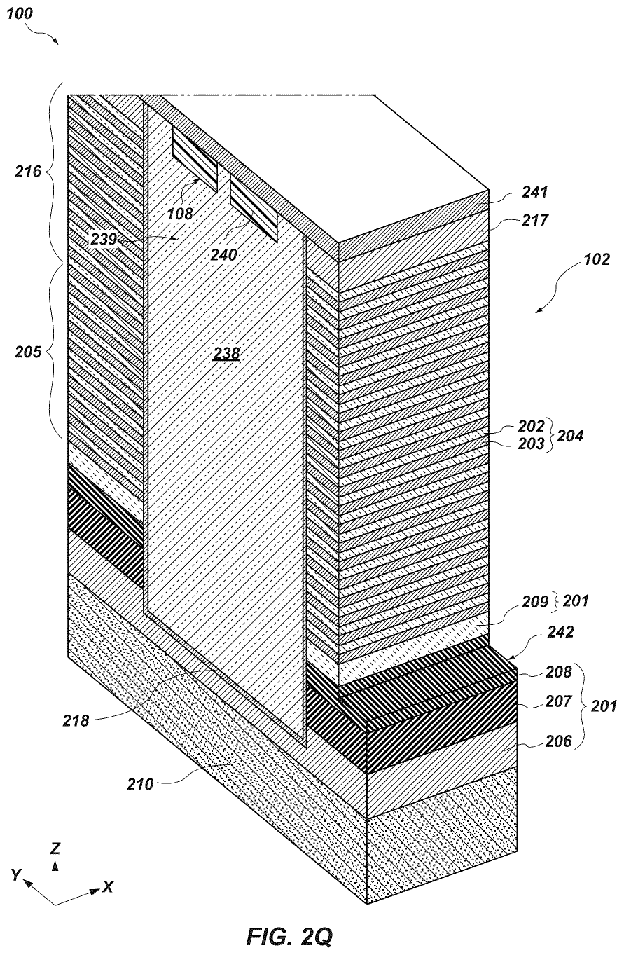

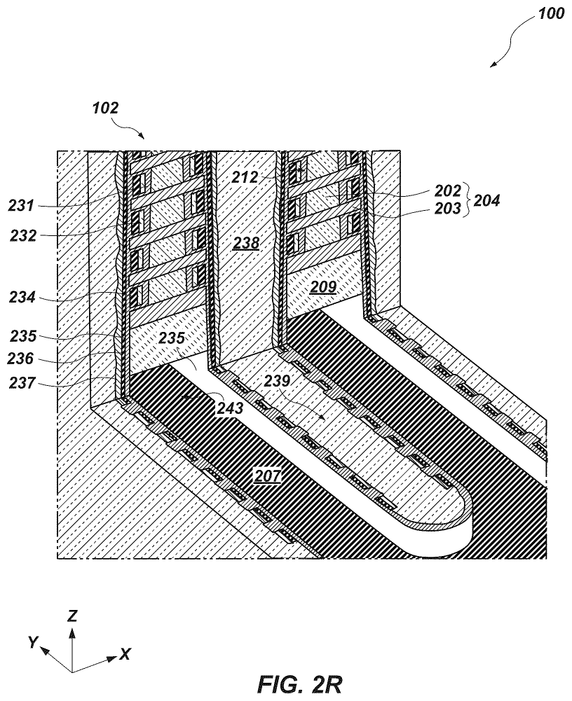

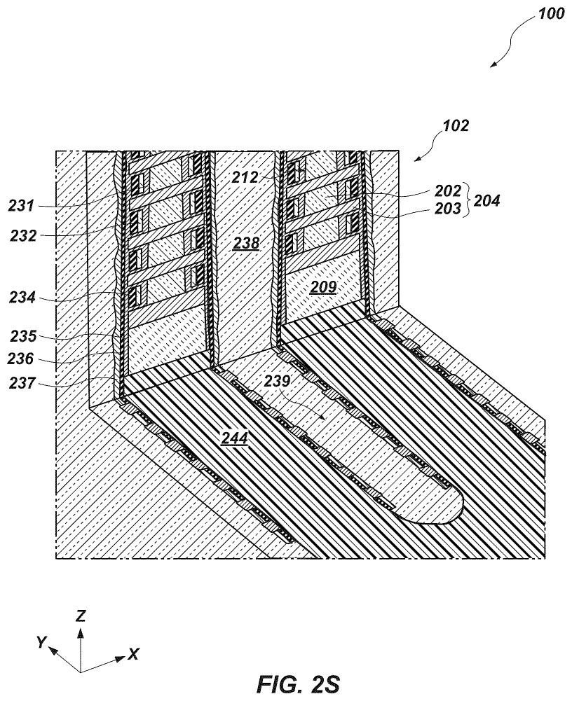

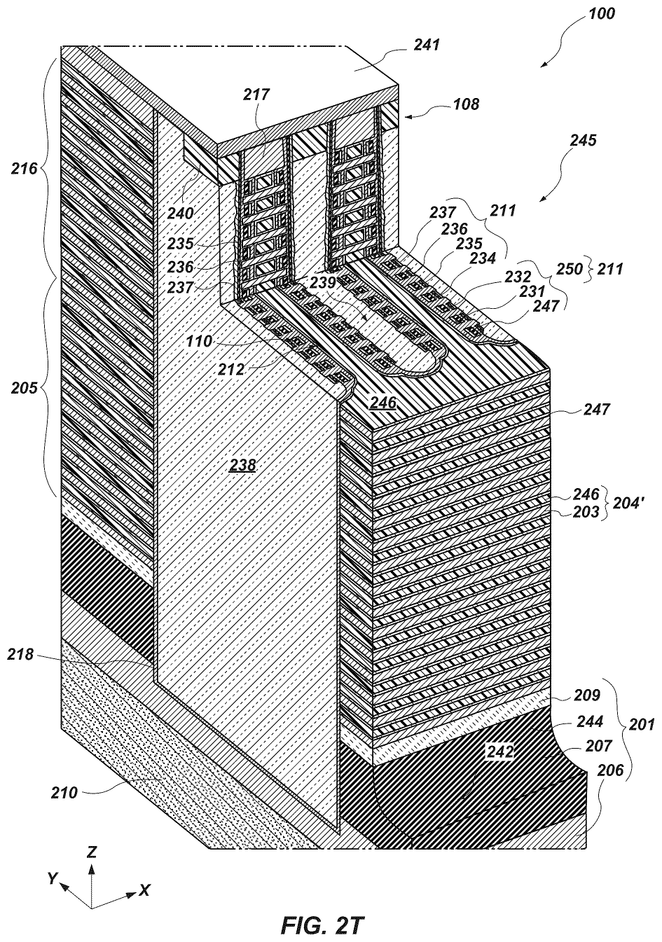

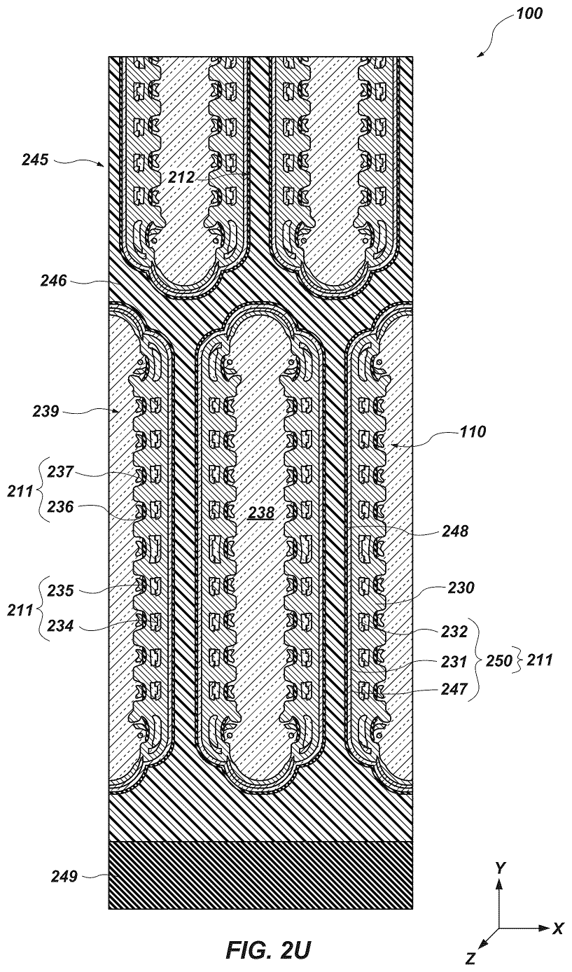

FIG. 1 and FIGS. 2A through 2U are various views (described in further detail below) illustrating a microelectronic device structure 100 at different processing stages of a method of forming a microelectronic device (e.g., a memory device, such as a 3D NAND Flash memory device), in accordance with embodiments of the disclosure. With the description provided below, it will be readily apparent to one of ordinary skill in the art that the structures (e.g., the microelectronic device structure 100) and devices (e.g., microelectronic devices) described herein may be employed in various relatively larger devices and/or systems. For clarity and case of understanding the drawings and associated description, not all features (e.g., regions, structures, materials, devices) of the microelectronic device structure 100 depicted in one or more of FIG. 1 and FIGS. 2A through 2U are depicted in the one or more other of FIG. 1 and FIGS. 2A through 2U.

FIG. 1 depicts a simplified, partial top-down view of a microelectronic device structure 100 at a processing stage of a method of forming a microelectronic device, in accordance with embodiments of this disclosure. The microelectronic device structure 100 may be formed to include a preliminary stack structure 102 over a base structure 201 (FIG. 2A). The microelectronic device structure 100 may include one or more first slots 104 (e.g., memory cell slits), second slot regions 106 (e.g., replacement gate regions), and third slot regions 108 (e.g., plug regions) therein. The first slots 104 may define voids vertically extending through the preliminary stack structure 102. The second slot regions 106 and the third slot regions 108 may define regions where voids may be formed at later processing stages.

The first slots 104 may include multiple, substantially linear voids in the preliminary stack structure 102. An individual first slot 104 may include a relatively long edge (e.g., horizontal boundary) horizontally extending in a first horizontal direction (e.g., the Y-direction) and a relatively short edge horizontally extending in a second horizontal direction (e.g., the X-direction) substantially orthogonal to the first horizontal direction. The first slots 104 may individually exhibit a single, oblong horizontal cross-sectional shape (e.g., an obround horizontal cross-sectional shape). Multiple first slots 104 horizontally aligned with one another in the Y-direction and horizontally offset from one another in the X-direction may form rows of first slots 104. Neighboring individual rows of first slots 104 may be horizontally partially offset from one another in the X-direction. Further, neighboring individual rows of first slots 104 may partially horizontally overlap one another in the X- and Y-directions. The first slots 104 may have a horizontal pitch in the X-direction (e.g., the distance from respective horizontal centers, defined in the X-direction, of adjacent first slots 104) within a range of from about 100 nm to about 300 nm, such as from about 125 nm to about 250 nm, from about 150 nm to about 200 nm, or about 170 nm. The first slots 104 may have a horizontal pitch in the Y-direction (e.g., the distance in the Y-direction between respective horizontal centers, defined in the Y-direction, of adjacent rows of the first slots 104) within a range of from about 200 nm to about 900 nm, such as from about 350 nm to about 700 nm, from about 500 nm to about 600 nm, or about 560 nm.

One or more memory cell regions 110 are at and around outer horizontal boundaries of individual first slots 104 (e.g., along the relatively long edges extending in the Y-direction). For an individual first slot 104, the memory cell regions 110 may individually be separated from neighboring memory cell regions 110 in the Y-direction. Further, pairs of individual memory cell regions 110 horizontally aligned within one another in the Y-direction may be separated by less than or equal to approximately the horizontal span, in the X-direction, of the first slot 104 associated therewith. An individual first slot 104 may be formed to have any desired number of the memory cell regions 110 associated therewith. By way of non-limiting example, the first slots 104 may individually be formed to include less than or equal to sixteen (16) of the memory cell regions 110 associated therewith, such as less than or equal to twelve (12) of the memory cell regions 110, such as less than or equal to eight (8) of the memory cell regions 110, such as less than or equal to four (4) of the memory cell regions 110. Alternatively, the first slots 104 may individually be formed to include greater than or equal to sixteen (16) of the memory cell regions 110 associated therewith, such as greater than or equal to thirty-two (32) of the memory cell regions 110, such as greater than or equal to sixty-four (64) of the memory cell regions 110.

The second slot regions 106 may individually comprise an elongate horizontal cross-sectional shape (e.g., a substantially rectangular horizontal cross-sectional shape). Individual second slot regions 106 may comprise a relatively long boundary horizontally extending in the X-direction, and a relatively short boundary horizontally extending in the Y-direction. Neighboring second slot regions 106 may be horizontally spaced from one another in the Y-direction, with multiple first slots 104 disposed therebetween. The second slot regions 106 may individually have a horizontal width in the Y-direction within a range of from about 100 nm to about 400 nm, such as from about 150 nm to about 350 nm, from about 200 nm to about 300 nm, or about 240 nm. The second slot regions 106 may have a horizontal pitch in the Y-direction within a range of from about 1000 nm to about 4000 nm, such as from about 1500 nm to about 3000 nm, from about 2000 nm to about 2500 nm, or about 2100 nm.

The third slot regions 108 may individually comprise an elongate horizontal cross-sectional shape (e.g., a substantially rectangular horizontal cross-sectional shape). Individual third slot regions 108 may comprise a relatively long boundary horizontally extending in the X-direction, and a relatively short boundary horizontally extending in the Y-direction. Neighboring pairs of third slot regions 108 may horizontally overlap a corresponding row of first slots 104. The third slot regions 108 may individually have a horizontal width in the Y-direction within a range of from about 50 nm to about 300 nm, such as from about 100 nm to about 250 nm, from about 125 nm to about 200 nm, or about 140 nm.

FIGS. 2A through 2U depict simplified, perspective, partial cutaway views of the microelectronic device structure 100 at different processing stages of a method of forming a microelectronic device. For clarity and ease of understanding the drawings and associated description, a section of the microelectronic device structure 100, indicated by region A shown with dashed lines in FIG. 1, is depicted in FIGS. 2A through 2U.

FIG. 2A is a simplified, partial perspective cross-sectional view of the microelectronic device structure 100 at the processing stage of forming the microelectronic device structure 100 depicted in FIG. 1. As shown in FIG. 2A, the microelectronic device structure 100 may be formed to include the preliminary stack structure 102 including a vertically alternating (e.g., in a Z-direction) sequence of sacrificial material 202 and insulative material 203 arranged in tiers 204. The tiers 204 of the preliminary stack structure 102 may individually include the sacrificial material 202 vertically neighboring (e.g., directly vertically adjacent in the Z-direction) the insulative material 203.

The insulative material 203 of the individual tiers 204 of the preliminary stack structure 102 may be formed of and include at least one dielectric material, such one or more of at least one dielectric oxide material (e.g., one or more of SiOₓ, phosphosilicate glass, borosilicate glass, borophosphosilicate glass, fluorosilicate glass, AlOₓ, HfOₓ, NbO—ₓ—, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the insulative material 203 of each of the tiers 204 of the preliminary stack structure 102 is formed of and includes a dielectric oxide material, such as SiOₓ (e.g., SiO₂). The insulative material 203 of each of the tiers 204 may be substantially homogeneous, or the insulative material 203 of one or more (e.g., each) of the tiers 204 may be heterogeneous.

The sacrificial material 202 of each of the tiers 204 of the preliminary stack structure 102 may be formed of and include at least one material (e.g., at least one insulative material) that may be selectively removed relative to the insulative material 203. The sacrificial material 202 may be selectively etchable relative to the insulative material 203 during common (e.g., collective, mutual) exposure to a first etchant; and the insulative material 203 may be selectively etchable to the sacrificial material 202 during common exposure to a second, different etchant. By way of non-limiting example, depending on the material composition of the insulative material 203, the sacrificial material 202 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbO—ₓ—, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}), and at least one semiconductive material (e.g., polycrystalline silicon). In some embodiments, the sacrificial material 202 of each of the tiers 204 of the preliminary stack structure 102 is formed of and includes a dielectric nitride material, such as SiN_{y} (e.g., Si₃N₄). The sacrificial material 202 may, for example, be selectively etchable relative to the insulative material 203 during common exposure to a wet etchant comprising phosphoric acid (H₃PO₄). The preliminary stack structure 102 may include one or more decks, each deck comprising multiple tiers 204. FIG. 2A depicts the preliminary stack structure 102 with a lower deck 205.

The base structure 201 may include multiple materials. For example, the base structure 201 may include a base dielectric material 206, a lower base structure material 207, a base sacrificial material 208, and an upper base structure material 209. The base dielectric material 206 may be formed of and include dielectric material. The lower base structure material 207 may be formed of and include semiconductor material, such as doped semiconductor material (e.g., N-type polysilicon). The base sacrificial material 208 may be formed of and include an additional semiconductor material, such as substantially undoped semiconductor material (e.g., undoped polysilicon). The upper base structure material 209 may be formed of and include an interlayer dielectric (ILD) material, such as a low-K dielectric material (e.g., silicon nitride, silicon oxycarbide, silicon oxynitride, hydrogenated silicon oxycarbide, silicon oxycarbonitride).

As shown in FIG. 2A, the microelectronic device structure 100 may further include a substrate 210 vertically underlying the base structure 201. The substrate 210 may comprise a structure or material upon which the base structure 201 is formed. In some embodiments, the substrate 210 comprises a semiconductor wafer (e.g., a silicon wafer). The substrate 210 may have additional features (e.g., regions, materials, structures, devices) at least partially formed therein. For example, the substrate 210, alone or in combination with the base structure 201, may include at least one control logic region including control logic devices configured to control various operations of other features (e.g., the vertical memory string structure 211 depicted in FIG. 2T) of the microelectronic device structure 100. As a non-limiting example, the control logic region includes one or more (e.g., each) of charge pumps (e.g., Vccp charge pumps, VNEGWI, charge pumps, DVC2 charge pumps), delay-locked loop (DLL) circuitry (e.g., ring oscillators), Vad regulators, drivers (e.g., string drivers), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. In some embodiments, the control logic region includes CMOS (complementary metal-oxide-semiconductor) circuitry. In such embodiments, the control logic region may be characterized as having a “CMOS under Array” (“CuA”) configuration.

The first slots 104 may individually be defined, prior to being filled with one or more materials, as negative space (e.g., trench, opening, slit) vertically extending within vertical boundaries of and at least partially defined by the preliminary stack structure 102, the upper base structure material 209, the base sacrificial material 208, the lower base structure material 207, and the base dielectric material 206. The first slots 104 may extend vertically (e.g., in the Z-direction) through the tiers 204 of the preliminary stack structure 102 and at least partially through the upper base structure material 209, the base sacrificial material 208, the lower base structure material 207, and the base dielectric material 206 of the base structure 201. As shown in FIG. 2A, the first slots 104 may comprise a lower (e.g., in the Z-direction) boundary at least partially defined by a surface of the base dielectric material 206 vertically positioned (e.g., in the Z-direction) below upper surfaces of the base dielectric material 206. The preliminary stack structure 102, the upper base structure material 209, the base sacrificial material 208, the lower base structure material 207, and the base dielectric material 206 may, in combination, include sidewalls 212 that define horizontal boundaries (e.g., in the X-direction, the Y-direction, and in horizontal directions that are a combination of the X- and Y-directions) of the first slots 104. Individual first slots 104 may be horizontally bounded by two opposing sidewalls 212 that face each other in the X-direction. A pair of opposing sidewalls 212 may form two (2) relatively long horizontal boundaries along the Y-direction of an individual first slot 104.

Still referring to FIG. 2A, the first slots 104 of the microelectronic device structure 100 may be filled with one or more materials to become filled slots. As shown in FIG. 2A, in some embodiments, the first slots 104 are individually partially filled with P-type polysilicon fill 213. The P-type polysilicon fill 213 may vertically (e.g., in the Z-direction) extend substantially the entire span of the first slots 104. The P-type polysilicon fill 213 may be formed of and include a doped polysilicon material including a P-type dopant (e.g., polysilicon doped with one or more of boron, aluminum, and gallium). The P-type polysilicon fill 213 may have an etch selectivity relative to the first slot liner material 214.

In addition, the P-type polysilicon fill 213 may be horizontally bounded by a first slot liner material 214, such that the first slot liner material 214 horizontally (e.g., in the X- and Y-directions) separates the P-type polysilicon fill 213 from the tiers 204 of the preliminary stack structure 102 and the upper base structure material 209, the base sacrificial material 208, the lower base structure material 207, and the base dielectric material 206 at the sidewalls 212 partially defining the first slots 104. The first slot liner material 214 may further vertically (e.g., in the Z-direction) separate the P-type polysilicon fill 213 from the base dielectric material 206. The first slot liner material 214 may be formed of and include dielectric material having etch selectivity relative to the P-type polysilicon fill 213, such as dielectric oxide material (e.g., silicon oxide).

The lower deck 205 may be formed by forming a vertically alternating sequence of the insulative material 203 and the sacrificial material 202. Following formation of the lower deck 205 of the preliminary stack structure 102, lower portions of the first slots 104 (e.g., at the vertical extent, in the Z-direction, of the lower deck 205 and the partial vertical extent of the base structure 201) may be formed by removing portions (e.g., via a patterned mask) of the materials of the lower deck 205 of the preliminary stack structure 102 and the base structure 201, thereby forming voids having respective horizontal profiles (e.g., when viewed from a top-down perspective) of the first slots 104.

Following formation of the lower portions of the first slots 104 within the preliminary stack structure 102 and the base structure 201, the first slot liner material 214 may be formed over exposed surfaces of the microelectronic device structure 100. The first slot liner material 214 may continuously extend over surfaces of the microelectronic device structure 100 defining the first slots 104. The first slot liner material 214 may substantially cover and continuously extend across the exposed surfaces of the sidewalls 212 partially defining the first slots 104. The first slot liner material 214 may further substantially cover and continuously extend across the exposed surfaces of the upper base structure material 209, base sacrificial material 208, lower base structure material 207, and base dielectric material 206 within the horizontal areas of the first slots 104.

Following formation of the first slot liner material 214, the P-type polysilicon fill 213 may be formed (e.g., non-conformally deposited) within remaining (e.g., unfilled) portions of the first slot 104. The P-type polysilicon fill 213 may be formed over the first slot liner material 214, and may substantially fill the first slots 104.

Following formation of the P-type polysilicon fill 213, portions of the P-type polysilicon fill 213 and the first slot liner material 214 overlying an uppermost surface (e.g., in the Z-direction) of the lower deck 205 may be removed (e.g., through an abrasive planarization process, such as a chemical-mechanical planarization (CMP) process). Removal of the P-type polysilicon fill 213 and the first slot liner material 214 may leave upper surfaces (e.g., in the Z-direction) of the P-type polysilicon fill 213 and the first slot liner material 214 substantially coplanar with upper surfaces of the lower deck 205 (e.g., an upper surface of the insulative material 203 of an uppermost tier 204 of the preliminary stack structure 102).

Referring to FIG. 2B, the P-type polysilicon fill 213 may be partially removed from horizontal central regions (e.g., in the Y-direction) of the first slots 104. The P-type polysilicon fill 213 may be partially removed by conventional material removal (e.g., patterning of mask material into the shape of the third slot regions 108 (FIG. 1) by photolithography, and selective anisotropic dry etching of the P-type polysilicon fill 213) techniques to pattern voids in the individual portions of the P-type polysilicon fill 213. The removal of the portion of the P-type polysilicon fill 213 may result in voids within horizontal areas of the first slots 104 (e.g., having a substantially rectangular horizontal cross-sectional shape) spanning substantially the vertical extent (e.g., in the Z-direction) of the individual first slots 104. The individual voids formed from the partial removal of the P-type polysilicon fill 213 may horizontally extend in the X-direction substantially the entire span between opposing portions of the first slot liner material 214 on the sidewalls 212 partially defining the individual first slots 104. P-type polysilicon fill 213 may remain in horizontal end regions (e.g., in the Y-direction) of individual first slots 104.

Following the partial removal of the P-type polysilicon fill 213, undoped semiconductor fill 215 may be formed (e.g., deposited) within horizontal areas of the individual first slots 104 in the voids where the P-type polysilicon fill 213 was removed. The undoped semiconductor fill 215 may substantially fill the void space within the horizontal central regions (e.g., in the Y-direction) of individual first slots 104, with the central region being bounded in the Y-direction by the horizontal end regions of the first slots 104 and bounded in the X-direction by the first slot liner material 214. Within the horizontal central region, the undoped semiconductor fill 215 may horizontally extend substantially the entire span in the X-direction of the individual first slots 104 between opposing portions of the first slot liner material 214 on the sidewalls 212 partially defining the individual first slots 104. The undoped semiconductor fill 215 may vertically (e.g., in the Z-direction) extend substantially the entire span of the first slots 104. The undoped semiconductor fill 215 may be formed of and include a semiconductor material, such as substantially undoped semiconductor material (e.g., undoped polysilicon).

Following formation of the undoped semiconductor fill 215, portions of the P-type polysilicon fill 213, undoped semiconductor fill 215, and first slot liner material 214 overlying an uppermost surface (e.g., in the Z-direction) of the lower deck 205 may be removed (e.g., through an abrasive planarization process, such as a CMP process). Removal of the P-type polysilicon fill 213, the undoped semiconductor fill 215, and the first slot liner material 214 may leave upper surfaces (e.g., in the Z-direction) of the P-type polysilicon fill 213, undoped semiconductor fill 215, and first slot liner material 214 substantially coplanar with upper surfaces of the lower deck 205 (e.g., an upper surface of the insulative material 203 of an uppermost tier 204 of the preliminary stack structure 102).

The preliminary stack structure 102 may be formed to include one or more decks, with each deck comprising multiple tiers 204. As depicted in FIG. 2C, the preliminary stack structure 102 may include the lower deck 205 and an upper deck 216 vertically overlying (e.g., in the Z-direction) the lower deck 205. The upper deck 216 may be formed over the lower deck 205 by forming a vertically alternating sequence of the sacrificial material 202 and the insulative material 203. Following formation of the upper deck 216, a top dielectric material 217 may be formed over the upper deck 216. The top dielectric material 217 may be formed of and include insulative material. The top dielectric material 217 may be vertically thicker (e.g., in the Z-direction) than the insulative material 203 and/or the sacrificial material 202 of individual tiers 204 of the preliminary stack structure 102.

The decks (e.g., lower deck 205, upper deck 216) of the preliminary stack structure 102 may individually include any desired number of tiers 204. By way of non-limiting example, the lower deck 205 and the upper deck 216 may individually include ten (10) tiers 204. Alternatively, the lower deck 205 and the upper deck 216 may individually include fewer than ten (10) tiers 204. As further non-limiting examples, the lower deck 205 and the upper deck 216 may individually include greater than or equal to ten (10) of the tiers 204, such as greater than or equal to sixteen (16) of the tiers 204, greater than or equal to thirty-two (32) of the tiers 204, greater than or equal to sixty-four (64) of the tiers 204, or greater than or equal to one hundred and twenty-eight (128) of the tiers 204.

Still referring to FIG. 2C, following formation of the upper deck 216 of the preliminary stack structure 102, upper portions of the first slots 104 (e.g., at the vertical extent, in the Z-direction, of the upper deck 216 and the top dielectric material 217) may be formed by removing portions (e.g., via a patterned mask) of the materials of the upper deck 216 and the top dielectric material 217, thereby forming voids having respective horizontal profiles of the first slots 104. The individual horizontal profiles of the upper portions of the first slots 104 may be substantially horizontally aligned (e.g., in the X- and Y-directions) with the individual horizontal profiles of the lower portions of the first slots 104. However, the upper portions of the first slots 104 may be partially horizontally (e.g., in the X- and/or Y-directions) offset (e.g., partially horizontally misaligned) with respect to the corresponding lower portions of the first slots 104, thereby resulting in an upper deck overhang. Additionally or alternatively, the sidewalls 212 partially defining the first slots 104 may exhibit a taper. If tapered, the sidewalls 212 may be positively sloped or may be negatively sloped. If tapered, the sidewalls 212 partially defining the first slots 104 may result in differently-sized horizontal profiles of portions of the first slots 104 within the lower deck 205 than additional portions of the first slots 104 within the upper deck 216. For example, at the interface between the lower deck 205 and the upper deck 216 within an individual first slot 104, the horizontal span in the X- and Y-directions between opposing sidewalls 212 partially defining the first slots 104 may vary from the upper deck 216 to the lower deck 205. A downward-facing lower (e.g., in the Z-direction) edge of the upper deck 216 may be exposed by the partial horizontal offset between the upper portions of the first slots 104 (e.g., at the upper deck 216) and the lower portions of the first slots 104 (e.g., at the lower deck 205). Alternatively, a horizontal offset between the upper portions of the first slots 104 and the lower portions of the first slots 104 may form a shoulder between the lower deck 205 and the upper deck 216. In such embodiments, an edge, facing upward in the Z-direction, of the lower deck 205 is exposed by the partial horizontal offset between the upper deck 216 and the lower deck 205. In additional embodiments, the preliminary stack structure 102 exhibits substantially no horizontal offset, horizontal misalignment, and/or taper between the lower deck 205 and the upper deck 216.

Following formation of the upper portions of the first slots 104 within the upper deck 216 and the top dielectric material 217, additional portions of the first slot liner material 214 may be formed at elevations (e.g., in the Z-direction) coincident with the upper deck 216 and the top dielectric material 217 by forming additional liner material over exposed surfaces of the microelectronic device structure 100. The additional liner material may substantially extend across the sidewalls 212 partially defining the upper portions of the first slots 104. As a result, the first slot liner material 214 may substantially cover and continuously extend across the exposed surfaces of the sidewalls 212 partially defining the upper portions of the first slots 104.

Following formation of the additional portions of the first slot liner material 214, portions of the first slot liner material 214 that were formed over (e.g., in the Z-direction) the P-type polysilicon fill 213 and the undoped semiconductor fill 215 may be removed from the first slots 104 (e.g., by anisotropic reactive ion etching). Removal of the portions of the first slot liner material 214 may expose upper surfaces (e.g., in the Z-direction) of the P-type polysilicon fill 213 and the undoped semiconductor fill 215 in the lower portions of the first slots 104. The first slot liner material 214 may remain on the sidewalls 212 partially defining the first slots 104.

Referring to FIG. 2D, following removal of portions of the first slot liner material 214, additional P-type polysilicon fill 213 may be formed (e.g., non-conformally deposited) within remaining (e.g., unfilled) upper portions of the first slots 104. The P-type polysilicon fill 213 may be formed over the first slot liner material 214, and may substantially fill the first slots 104 within and over the upper portions of the first slots 104 (e.g., substantially filling the individual upper portions of the first slots 104 with the P-type polysilicon fill 213). The P-type polysilicon fill 213 may continuously span substantially the vertical extent (e.g., in the Z-direction) of the upper deck 216 and the top dielectric material 217 within substantially the entire horizontal profile (e.g., in the X- and Y-directions) of the first slots 104. The P-type polysilicon fill 213 may be formed to substantially extend across and at least partially cover the exposed upper surfaces, in the Z-direction, of the P-type polysilicon fill 213 and the undoped semiconductor fill 215 in the lower portions of the first slots 104. Further, the P-type polysilicon fill 213 may be formed to substantially extend across and at least partially cover the exposed upper surfaces, in the Z-direction, of the top dielectric material 217.

Following formation of the P-type polysilicon fill 213, portions of the P-type polysilicon fill 213 and the first slot liner material 214 overlying an uppermost surface (e.g., in the Z-direction) of the top dielectric material 217 may be removed (e.g., through an abrasive planarization process, such as a CMP process). Removal of the P-type polysilicon fill 213 and the first slot liner material 214 may leave upper surfaces (e.g., in the Z-direction) of the P-type polysilicon fill 213 and the first slot liner material 214 substantially coplanar with upper surfaces of the top dielectric material 217.

Still referring to FIG. 2D, the P-type polysilicon fill 213 may be partially removed from horizontal central regions (e.g., in the Y-direction) of the first slots 104 at vertical elevations of the upper deck 216 and the top dielectric material 217. The P-type polysilicon fill 213 may be partially removed by conventional material removal (e.g., patterning of mask material into the shape of the third slot regions 108 (FIG. 1) by photolithography, and selective anisotropic dry etching of the P-type polysilicon fill 213) techniques to pattern voids in the individual portions of the P-type polysilicon fill 213. The removal of the portion of the P-type polysilicon fill 213 may result in voids within horizontal areas of the first slots 104 (e.g., having a substantially rectangular horizontal cross-sectional shape) spanning substantially the vertical extent (e.g., in the Z-direction) of the upper portions of the individual first slots 104. The individual voids formed from the partial removal of the P-type polysilicon fill 213 may horizontally extend in the X-direction substantially the entire span between opposing portions of the first slot liner material 214 on the sidewalls 212 partially defining the individual first slots 104. P-type polysilicon fill 213 may remain in horizontal end regions (e.g., in the Y-direction) of individual first slots 104.

Following the partial removal of the P-type polysilicon fill 213, the undoped semiconductor fill 215 may be substantially removed (e.g., exhumed) from the lower portions of the individual first slots 104. Removal of the undoped semiconductor fill 215 may result in an upward-facing (e.g., in the Z-direction) portion of the first slot liner material 214, defining a lower boundary in the Z-direction of the first slots 104, being exposed. Removal of the undoped semiconductor fill 215 may further result in the first slots 104 individually comprising horizontal end regions (e.g., in the Y-direction) filled with P-type polysilicon fill 213 at substantially the entire vertical extent (e.g., in the Z-direction) of the first slots 104. Removal of the undoped semiconductor fill 215 may further result in the first slots 104 individually comprising void space within the horizontal central regions (e.g., in the Y-direction) of the first slots 104 along substantially the entire vertical extent (e.g., in the Z-direction) of the first slots 104.

FIGS. 2E, 2F, and 2H through 2P show enlarged, perspective, partial cutaway views of a sub-section B (shown with dashed lines in FIG. 2D) of the region A (FIG. 1), depicting portions of the upper deck 216 of the preliminary stack structure 102, at different additional processing stages of the method of forming a microelectronic device following the processing stage described above with reference to FIG. 2D. For clarity and case of understanding the drawings and associated description, the section of the microelectronic device structure 100 depicted in FIGS. 2A through 2D is depicted in FIGS. 2E, 2F, and 2H through 2P, with the microelectronic device structure 100 further sectioned horizontally (e.g., at the XY-plane) and vertically (e.g., at the XZ-plane) at the sub-section B (FIG. 2D), hiding a portion of the upper deck 216 from view. As shown in FIG. 2E, following removal of the undoped semiconductor fill 215, exposed portions of the P-type polysilicon fill 213 may be removed (e.g., recessed) at a horizontal extent in the Y-direction from the horizontal center of the individual first slots 104. Removing the portions of the P-type polysilicon fill 213 may expose corresponding portions of the first slot liner material 214 on the sidewalls 212 partially defining the individual first slots 104.

Following removal of portions of the P-type polysilicon fill 213, exposed portions of the first slot liner material 214 may be removed from the sidewalls 212 partially defining the first slots 104. Removal of the exposed portions of the first slot liner material 214 may expose the insulative material 203 and sacrificial material 202 of the tiers 204 of the preliminary stack structure 102 within the horizontal areas of the first slots 104. Additionally, removal of exposed portions of the first slot liner material 214 may leave first slot liner material 214 at the horizontal ends (e.g., in the Y-direction) of the individual first slots 104, adjacent to and covered by remaining portions of the P-type polysilicon fill 213. Individual remaining portions of the first slot liner material 214 may comprise a horizontal profile of an arc segment that separates the P-type polysilicon fill 213 from the tiers 204 of the preliminary stack structure 102.

It may be desirable to form select gate transistors (e.g., metal-oxide-semiconductor (MOS) select gate transistors) at one or more of the uppermost tiers 204 (e.g., in the Z-direction). To form select gate transistor structures, a barrier material (e.g., photoresist) may be formed over the first slot liner material 214 at elevations coincident with the one or more uppermost tiers 204 to prevent or mitigate removal of the first slot liner material 214 as described above and to prevent or mitigate recess of the sacrificial material 202 from the one or more uppermost tiers 204 as described below. The barrier material may remain in place during subsequent processing steps, described below with respect to FIGS. 2E through 20, to substantially maintain the sacrificial material 202 in the one or more uppermost tiers 204 and the first slot liner material 214 horizontally adjacent thereto.

Following removal of exposed portions of the first slot liner material 214, portions of the sacrificial material 202 of the tiers 204 of the preliminary stack structure 102 may be removed (e.g., recessed) via the first slots 104. As shown in FIG. 2E, portions of the sacrificial material 202 are removed so that exposed surfaces (e.g., facing the X-direction) of the remaining sacrificial material 202 portions are individually recessed in the X-direction from the horizontal centers of the first slots 104 with respect to vertically adjacent portions of insulative material 203.

Following removal of portions of the sacrificial material 202 from the tiers 204 of the preliminary stack structure 102, a liner oxide material 218 may be formed (e.g., by oxidization of portions of the sacrificial material 202 and the P-type polysilicon fill 213) on or over portions of the sacrificial material 202 and the P-type polysilicon fill 213 that are exposed by the first slots 104. The liner oxide material 218 may be formed to substantially extend across and at least partially cover the exposed surfaces of the sacrificial material 202 of the tiers 204 of the preliminary stack structure 102 within the horizontal areas of the first slots 104. Individual portions of the liner oxide material 218 may vertically span (e.g., in the Z-direction) between respective portions of insulative material 203 of neighboring tiers 204. Additionally, the liner oxide material 218 may be formed to continuously span substantially the vertical extent in the Z-direction and the horizontal extent in the X-direction of the P-type polysilicon fill 213 within the horizontal areas of the first slots 104.

The liner oxide material 218 may be formed by exposing the sacrificial material 202 and the P-type polysilicon fill 213 to at least one oxidizing agent to convert the exposed portions of the sacrificial material 202 and the P-type polysilicon fill 213 to the liner oxide material 218. The first slot liner material 214 may be horizontal thicker (e.g., in the X- and Y-directions and combinations thereof) than the liner oxide material 218. The liner oxide material 218 and the first slot liner material 214 may have substantially the same material composition as one another, or may have different material compositions than one another.

Referring to FIG. 2F, following formation of the liner oxide material 218, an undoped semiconductor mask material 219 may be formed (e.g., deposited) over exposed surfaces of the microelectronic device structure 100. The undoped semiconductor mask material 219 may substantially extend across and at least partially cover surfaces of the microelectronic device structure 100 exposed by the first slots 104 (e.g., exposed surfaces of the insulative material 203 and liner oxide material 218). The undoped semiconductor mask material 219 may conform to a topography of vertically extending surfaces of the insulative material 203 and liner oxide material 218. The undoped semiconductor mask material 219 may be formed to have a vertical extent (e.g., in the Z-direction) substantially vertically aligned with the upper deck 216 and the lower deck 205. The undoped semiconductor mask material 219 may be formed of and include substantially undoped semiconductor material, such as substantially undoped polysilicon. The undoped semiconductor mask material 219 may have an etch selectivity relative to the liner oxide material 218, the first slot liner material 214, and each of a P-type polysilicon mask material 220, a trim material 221, and a sacrificial fill material 222 (FIG. 2G) subsequently formed thereover. Following formation of the undoped semiconductor mask material 219, portions of the undoped semiconductor mask material 219 extending beyond, in the X-direction, vertically adjacent portions of insulative material 203 toward the horizontal center of the individual first slots 104 may be partially removed (e.g., recessed).

Following the partial removal of the undoped semiconductor mask material 219, the P-type polysilicon mask material 220 may be formed on or over exposed surfaces of the undoped semiconductor mask material 219, the insulative material 203 of the tiers 204, and the top dielectric material 217. The P-type polysilicon mask material 220 may substantially extend across and at least partially cover the surfaces of the microelectronic device structure 100 exposed by the first slots 104. The P-type polysilicon mask material 220 may conform to a topography of the exposed surfaces of the undoped semiconductor mask material 219, the insulative material 203 of the tiers 204, and the top dielectric material 217. The P-type polysilicon mask material 220 may be formed to have a vertical extent (e.g., in the Z-direction) substantially coextensive with the vertical extent of the first slots 104. The P-type polysilicon mask material 220 may be formed of and include a polysilicon material including a P-type dopant (e.g., polysilicon doped with one or more of boron, aluminum, and gallium). The P-type polysilicon mask material 220 may have an etch selectivity relative to the undoped semiconductor mask material 219, the liner oxide material 218, the first slot liner material 214, the trim material 221, and the sacrificial fill material 222 (FIG. 2G) (e.g., boron-doped silicate glass). The formation of the P-type polysilicon mask material 220 may include forming the P-type polysilicon mask material 220 at a thickness substantially greater than a desired final thickness of the P-type polysilicon mask material 220. Following formation of the P-type polysilicon mask material 220, portions of the P-type polysilicon mask material 220 may be partially removed (e.g., recessed) in the X-direction to result in a relatively thinner remaining portion, in the X-direction, of the P-type polysilicon mask material 220 extending over the undoped semiconductor mask material 219 and insulative material 203 of the preliminary stack structure 102.

Following formation of the P-type polysilicon mask material 220, the trim material 221 may be formed on or over exposed surfaces of the P-type polysilicon mask material 220. The trim material 221 may substantially extend across and at least partially cover the exposed surfaces of the microelectronic device structure 100 within horizontal areas of the first slots 104. The trim material 221 may conform to a topography of exposed surfaces (e.g., exposed vertically extending surfaces) of the P-type polysilicon mask material 220. The trim material 221 may be formed to have a vertical extent (e.g., in the Z-direction) substantially coextensive with the vertical extent of the first slots 104. The trim material 221 may be formed of and include at least one material having different etch selectivity than the undoped semiconductor mask material 219, the liner oxide material 218, the first slot liner material 214, the P-type polysilicon mask material 220, and the sacrificial fill material 222 (FIG. 2G). In some embodiments, the trim material 221 is formed of and includes a dielectric nitride material (e.g., silicon nitride). In additional embodiments, the trim material 221 is formed of and includes a dielectric nitride material and an additional material (also referred to herein as a core material) having a different material composition than the dielectric nitride material on or over the dielectric nitride material.

For clarity and case of understanding the drawings and associated description, an enlarged portion of the section A of the microelectronic device structure 100, as depicted in FIGS. 2A through 2D, is depicted in FIG. 2G, with upper portions (e.g., in the Z-direction). FIG. 2G shows, without limitation, enlarged views of the preliminary stack structure 102 and the top dielectric material 217. Referring to FIG. 2G, following formation of the trim material 221, a sacrificial fill material 222 may be formed (e.g., non-conformally deposited) within remaining (e.g., unfilled) portions of the first slots 104 to substantially fill the first slots 104. The sacrificial fill material 222 may be formed of and include at least one material having an etch selectivity relative to the undoped semiconductor mask material 219, the P-type polysilicon mask material 220, the liner oxide material 218, the first slot liner material 214, and the trim material 221. In some embodiments, the sacrificial fill material 222 is formed of and includes boron-doped silicate glass.

Following formation of the sacrificial fill material 222, a cover material 223 may be formed over (e.g., in the Z-direction) the top dielectric material 217. The cover material 223 may be formed on or over a substantially planar upper horizontal surface defined by and including the coplanar upper horizontal surfaces of the top dielectric material 217, the first slot liner material 214, the P-type polysilicon fill 213, the liner oxide material 218, the undoped semiconductor mask material 219 (FIG. 2F), the P-type polysilicon mask material 220, the trim material 221, and the sacrificial fill material 222. The cover material 223 may have a substantially planar upper (e.g., in the Z-direction) horizontal surface. The cover material 223 may be formed of and include a dielectric oxide material (e.g., silicon oxide). In some embodiments, the cover material 223 comprises silicon oxide (e.g., SiO₂) formed (e.g., via deposition) using tetraeythlorthosilicate (“TEOS”) as a silicon source.

Following formation of the cover material 223, a portion thereof vertically overlying and horizontally overlapping individual horizontal profiles of the P-type polysilicon fill 213 (FIG. 2F) may be removed (e.g., by an etching process). As shown in FIG. 2G, the removal of the portion of the cover material 223 may result in a cover material gap 224 (e.g., trench, opening) vertically overlying (i.e., in the Z-direction) and horizontally overlapping (e.g., in the X-direction and the Y-direction) a horizontal profile of a portion of the P-type polysilicon fill 213 (FIG. 2F) and the first slot liner material 214 within the horizontal areas of the first slots 104. Further, the remaining cover material 223 may vertically overlie (i.e., in the Z-direction) and horizontally overlap (e.g., in the X-direction and the Y-direction) the undoped semiconductor mask material 219, the P-type polysilicon mask material 220, the trim material 221, and the sacrificial fill material 222.

The cover material gap 224 may have an elongate horizontal cross-sectional profile (e.g., a rectangular horizontal cross-sectional profile) that exposes at least some of an upper surface of the P-type polysilicon fill 213 and of the first slot liner material 214 without exposing the liner oxide material 218, the undoped semiconductor mask material 219, the P-type polysilicon mask material 220, the trim material 221, and the sacrificial fill material 222. In some embodiments, the cover material gap 224 only partially (e.g., less than completely) exposes the upper surfaces of the P-type polysilicon fill 213 and of the first slot liner material 214.

Following formation of the cover material 223 and the cover material gap 224, the P-type polysilicon fill 213 (FIG. 2F) may be removed (e.g., exhumed) from the first slots 104 via the cover material gap 224. Removal of the P-type polysilicon fill 213 from horizontal end regions (e.g., in the Y-direction) of the first slots 104 may result in an end region void 225 extending vertically (e.g., in the Z-direction) substantially the vertical extent of the first slots 104. Additionally, removal of the P-type polysilicon fill 213 from the first slots 104 may expose portions of the liner oxide material 218 and the first slot liner material 214 to the end region voids 225.

Referring to FIG. 2H, which again depicts the view of the microelectronic device structure 100 shown in FIG. 2F, but after the processing stage described above with reference to FIG. 2G, following removal of the P-type polysilicon fill 213, exposed portions of the liner oxide material 218 and of the first slot liner material 214 adjacent to the end region voids 225 may be removed (e.g., etched) from the first slots 104. Portions of the liner oxide material 218 and the first slot liner material 214 may be removed through separate material removal process (e.g., separate wet etching acts). Alternatively, portions of the liner oxide material 218 and the first slot liner material 214 may be removed jointly (e.g., using a single processing act). Removing the portions of the liner oxide material 218 may expose portions of the undoped semiconductor mask material 219 to the end region voids 225 in the first slots 104. The first slot liner material 214 and the liner oxide material 218 may exhibit similar etch removal rates. However, due to the first slot liner material 214 being horizontal thicker than the liner oxide material 218, upon removing substantially all of the liner oxide material 218 adjacent to the end region voids 225, some portions of the first slot liner material 214 (e.g., portions directly adjacent to the sacrificial material 202) may remain in place. As a result of the removal of portions of the liner oxide material 218 and the first slot liner material 214, the horizontal profile of the individual end region voids 225 may increase in size.

Following removal of portions of the liner oxide material 218 and of the first slot liner material 214, exposed portions of the undoped semiconductor mask material 219 (e.g., portions directly adjacent to the end region void 225) may be removed (e.g., via non-selective etching). The horizontal extent in the X-direction of the undoped semiconductor mask material 219 removed may substantially span the individual end region voids 225. Additionally, within such a horizontal span in the X-direction, substantially the entire horizontal span in the Y-direction of the undoped semiconductor mask material 219 may be removed. As a result, removing the exposed portions of the undoped semiconductor mask material 219 in the end region voids 225 may expose portions of the P-type polysilicon mask material 220 to the end region voids 225. The horizontal portions of the undoped semiconductor mask material 219 may be removed along substantially the entire vertical extent (e.g., in the Z-direction) of the preliminary stack structure 102. As a result of the removal of portions of the undoped semiconductor mask material 219, the horizontal profile of the individual end region voids 225 may increase in size.

Referring to FIG. 2I, following removal of portions of the undoped semiconductor mask material 219, exposed portions of the P-type polysilicon mask material 220 (e.g., portions directly adjacent to the end region void 225) and exposed portions of the undoped semiconductor mask material 219 may be removed (e.g., etched). The horizontal extent in the X-direction of the P-type polysilicon mask material 220 removed may substantially span the individual end region voids 225. Additionally, within such a horizontal span in the X-direction, substantially the entire horizontal span in the Y-direction of the P-type polysilicon mask material 220 may be removed. Accordingly, removing the exposed portions of the P-type polysilicon mask material 220 in the end region voids 225 may expose portions of the trim material 221 to the end region voids 225. The horizontal portions of the P-type polysilicon mask material 220 may be removed along substantially the entire vertical extent (e.g., in the Z-direction) of the first slots 104. As a result of the removal of portions of the P-type polysilicon mask material 220, the horizontal profile of the individual end region voids 225 may increase in size. Removal of portions of the undoped semiconductor mask material 219 may horizontally recede the undoped semiconductor mask material 219 in the Y-direction away from the individual end region voids 225. Exposed portions of the undoped semiconductor mask material 219 and the P-type polysilicon mask material 220 facing the Y-direction may jointly form first edges 226. Such portions of the undoped semiconductor mask material 219 and the P-type polysilicon mask material 220 comprising an individual first edge 226 may be substantially horizontally aligned with each other in the Y-direction, or may be horizontally offset in the Y-direction from each other. Due to etch selectivity with respect to the undoped semiconductor mask material 219 and the P-type polysilicon mask material 220, removal of undoped semiconductor mask material 219 may be effectuated at a relatively higher rate than removal of P-type polysilicon mask material 220. By way of non-limiting example, the etch rate of undoped semiconductor mask material 219 may be from approximately 1.5 times faster to approximately 4 times faster than the etch rate of P-type polysilicon mask material 220, such as from approximately 1.75 times faster to approximately 3 times faster, such as approximately 2 times faster.

Referring next to FIG. 2J, following removal of portions of the P-type polysilicon mask material 220, a series of trim-etch cycles may be effectuated to successively form one or more preliminary separator structures 227 within the horizontal areas of the first slots 104. The preliminary separator structures 227 may be formed between, in the X-direction, the sidewalls 212 partially defining the first slots 104 and neighboring portions of the trim material 221. The completion of an individual trim-etch cycle may result in the formation of a group of one or more preliminary separator structures 227 at corresponding first edges 226 of the undoped semiconductor mask material 219 and the P-type polysilicon mask material 220. After formation of a first group of the preliminary separator structures 227 by way of a first trim-etch cycle, a second group of the preliminary separator structures 227 may be formed by way of a second trim-etch cycle, a third group of the preliminary separator structures 227 may be formed by way of a third trim-etch cycle, and so on, until the series of trim-etch cycles is completed. Individual preliminary separator structures 227 may exhibit a horizontal pitch, in the Y-direction, with respect to neighboring preliminary separator structures 227, which may correspond to a pitch of the memory cell regions 110 (FIG. 1). The pitch, in the Y-direction, between horizontally neighboring preliminary separator structures 227 may be substantially equivalent to the width, in the Y-direction, of one of the preliminary separator structures 227 combined with the width, in the Y-direction, of the space between horizontally neighboring preliminary separator structures 227. Spaces between neighboring preliminary separator structure 227, in the Y-direction, may define the memory cell regions 110.

The preliminary separator structures 227 may be formed at exposed first edges 226 of the undoped semiconductor mask material 219 and the P-type polysilicon mask material 220. The preliminary separator structures 227 may comprise an oxide material. The exposed portions (e.g., first edges 226) of the undoped semiconductor mask material 219 and the P-type polysilicon mask material 220 may be exposed to at least one oxidizing agent to form the preliminary separator structures 227. The process may substantially transform (e.g., convert, oxidize) some material of the undoped semiconductor mask material 219 and the P-type polysilicon mask material 220 into oxide (e.g., by thermal oxidation or plasma oxidation) of the preliminary separator structures 227. The individual preliminary separator structures 227 may be formed to continuously span a horizontal width in the X-direction between corresponding portions of the trim material 221 and the liner oxide material 218 within the horizontal areas of the first slots 104. Further, the individual preliminary separator structures 227 may continuously span substantially an entire vertical extent (e.g., in the Z-direction) of the first slot 104.

Referring to FIG. 2K, an individual trim-etch cycle may include removing exposed portions of the trim material 221 (e.g., portions closest to the end region void 225). Removing portions of the trim material 221 may expose portions of the sacrificial fill material 222 to the end region voids 225. As a result of the removal of portions of the trim material 221, the horizontal profile of the individual end region voids 225 may increase in size. Additionally, exposed portions of the trim material 221 directly adjacent in the X-direction to the sacrificial fill material 222 may be removed (e.g., trimmed back). Removal of portions of the trim material 221 may horizontally recede the trim material 221 in the Y-direction away from the nearest individual end region void 225, so that a second edge 228 of the trim material 221 is positioned farther in the Y-direction from the end region void 225 than the first edge 226 of the undoped semiconductor mask material 219 and the P-type polysilicon mask material 220. As such, a horizontal gap 229 may be formed between the second edge 228 of the trim material 221 and the previously-formed preliminary separator structure 227, exposing additional portions (e.g., unoxidized portions) of the P-type polysilicon mask material 220.

Removing the portion of trim material 221 may include subjecting the trim material 221 to at least one etchant (e.g., hot phosphoric acid etchant). The etchant may be introduced to the second edges 228, which are exposed to the end region voids 225 in the first slots 104, by way of the cover material gap 224 (FIG. 2G). In this manner, the material removal process may be carried out to progressively remove portions of the trim material 221. The horizontal extent in the Y-direction of the trim material 221 removed (e.g., trimmed back) may be controlled, as desired, by choosing an etchant composition according to predetermined etching rates, by choosing the duration of the material removal process, and/or by choosing other parameters of the material removal process.

Following trimming back a portion of the trim material 221, exposed portions of the undoped semiconductor mask material 219 and the P-type polysilicon mask material 220 may be receded in the Y-direction. The extent of removal of the undoped semiconductor mask material 219 and the P-type polysilicon mask material 220 in the Y-direction may be substantially equivalent to the pitch of the memory cell regions 110. The horizontal extent of the removal of the undoped semiconductor mask material 219 and the P-type polysilicon mask material 220 in the Y-direction may be controlled, as desired, by choosing an etchant composition according to predetermined etching rates, by choosing the duration of the material removal process, and/or by choosing other parameters of the material removal process. Removal of portions of the undoped semiconductor mask material 219 and the P-type polysilicon mask material 220 may horizontally recede the undoped semiconductor mask material 219 and the P-type polysilicon mask material 220 in the Y-direction away from the nearest individual end region void 225, so that the first edge 226 is relocated farther away, in the Y-direction, from the end region void 225.

Following removal of portions of the undoped semiconductor mask material 219 and the P-type polysilicon mask material 220, additional preliminary separator structures 227 may be formed at the newly exposed first edges 226 of the undoped semiconductor mask material 219 and the P-type polysilicon mask material 220. FIG. 2K shows the results of a second trim-etch cycle, having formed a second preliminary separator structure 227 near the end region void 225 and along an individual sidewall 212 partially defining the first slot 104 (e.g., four (4) preliminary separator structures 227 near the individual end region void 225). Although not depicted in FIG. 2K, additional preliminary separator structures 227 may be formed within the opposite horizontal half (e.g., in the Y-direction) of each of the first slots 104. Thus, each trim-etch cycle may result in the formation of four (4) preliminary separator structures 227 within a horizontal area of an individual first slot 104.

Referring to FIG. 2L, one or more additional trim-etch cycles may be effectuated to form additional preliminary separator structures 227 along the sidewalls 212 partially defining the first slots 104, wherein each subsequently-formed preliminary separator structure 227 may be positioned farther, in the Y-direction, from a respective end region void 225 than the previously-formed preliminary separator structures 227. As shown in FIG. 2L, five (5) preliminary separator structures 227 have been formed along each sidewall 212 partially defining the first slots 104 within each half (e.g., in the Y-direction) of the first slots 104.

A quantity of preliminary separator structures 227 within an individual first slot 104 may be equal to four times (4×) a quantity of trim-etch cycles effectuated. The quantity of preliminary separator structures 227 within the horizontal area of an individual first slot 104 may be determined, in part, by the horizontal length (e.g., in the Y-direction) of the first slot 104 and the horizontal pitch (e.g., in the Y-direction) of the memory cell regions 110 associated therewith. The memory cell regions 110 may each have substantially the same horizontal width in the Y-direction as one another, or one or more of the memory cell regions 110 may have a different horizontal width than one or more other of the memory cell regions 110. In addition, the preliminary separator structures 227 may each have substantially the same horizontal width in the Y-direction as one another, or one or more of the preliminary separator structures 227 may have a different horizontal width than one or more other of the preliminary separator structures 227. Individual preliminary separator structures 227 may be horizontally interposed in the Y-direction between neighboring memory cell regions 110. In some embodiments, an individual first slot 104 has a group of eight (8) of the memory cell regions 110 on each of the two (2) opposing sidewalls 212 partially defining the first slot 104. In other embodiments, an individual first slot 104 has seven (7) or fewer memory cell regions 110 on each of the two opposing sidewalls 212 partially defining the first slot 104. In other embodiments, an individual first slot 104 has nine (9) or more memory cell regions 110 on each of the two opposing sidewalls 212 partially defining the first slot 104.

During individual processing stages of an individual trim-etch cycle, multiple first slots 104 may be substantially synchronously (e.g., simultaneously) acted upon. By way of non-limiting example, if multiple first slots 104 are to individually have a group of sixteen (16) memory cell regions 110 formed therein (e.g., eight (8) memory cell regions 110 per sidewall 212 partially defining the individual first slot 104), four (4) trim-etch cycles may be conducted as described above, thereby forming sixteen (16) of the memory cell regions 110 within each of the first slots 104.

Referring to FIG. 2M, following completion of the series of trim-etch cycles, remaining portions of the sacrificial fill material 222, the trim material 221, the P-type polysilicon mask material 220, and the undoped semiconductor mask material 219 (FIG. 2L) may be substantially removed (e.g., exhumed) from the first slots 104. Additionally, the cover material 223 may be substantially removed (e.g., by an etching process). The cover material 223 may be substantially completely removed from over (e.g., in the Z-direction) the top dielectric material 217. The sacrificial fill material 222, the trim material 221, the P-type polysilicon mask material 220, the undoped semiconductor mask material 219, and/or the cover material 223 may be removed individually (e.g., using separate discrete processing acts) or together (e.g., using a single processing act). In additional embodiments, the cover material 223 is at least partially (e.g., substantially) maintained (e.g., is not substantially removed) until after the completion of the processing stage described hereinbelow with reference to FIG. 2O.

Referring to FIG. 2N, following removal of remaining portions of the P-type polysilicon mask material 220, additional oxide material (e.g., dielectric oxide material) may be formed to substantially cover and continuously extend across the exposed surfaces of the preliminary separator structures 227 (FIG. 2M) and the liner oxide material 218 (FIG. 2M) to convert the preliminary separator structures 227 into separator structures 230 and to convert portions of the liner oxide material 218 (FIG. 2M) spanning between adjacent separator structures 230, in the Y-direction, into a middle dielectric material 231. In converting the preliminary separator structures 227 to the separator structures 230, individual preliminary separator structures 227 may increase in size in the Y-direction. In converting the liner oxide material 218 to the middle dielectric material 231, the liner oxide material 218 may increase in size in the X-direction. The middle dielectric material 231 may be formed of and include a high-K dielectric material. In some embodiments, the middle dielectric material 231 is formed of and includes silicon oxide. Horizontal gaps in the Y-direction between adjacent separator structures 230 may comprise recesses that define individual memory cell regions 110, individual adjacent memory cell regions 110 being separated in the Y-direction by separator structures 230.

Following formation of the separator structures 230 and the middle dielectric material 231, an inner dielectric material 232 may be formed over exposed surfaces of the separator structures 230 and the middle dielectric material 231 within the horizontal areas of the first slots 104. The inner dielectric material 232 may substantially extend across and at least partially cover the exposed surfaces of the separator structures 230 and the middle dielectric material 231. The inner dielectric material 232 may conform to a topography of vertically extending surfaces of the separator structures 230 and the middle dielectric material 231. The inner dielectric material 232 may be formed to have a vertical extent (e.g., in the Z-direction) substantially vertically aligned with the first slots 104. The inner dielectric material 232 may be formed of and include high-K dielectric material, such as high-K dielectric oxide material (e.g., one or more of hafnium oxide (HfOₓ), niobium oxide (NbOₓ), titanium oxide (TiOₓ), aluminum oxide (AlOₓ), and zirconium oxide (ZrOₓ)).

Following formation of the inner dielectric material 232, a sacrificial polysilicon material 233 may be formed over exposed surfaces of the inner dielectric material 232 within the horizontal areas of the first slots 104. The sacrificial polysilicon material 233 may substantially extend across and at least partially cover the exposed surfaces of the inner dielectric material 232. The sacrificial polysilicon material 233 may conform to a topography of vertically extending surfaces of the inner dielectric material 232. The sacrificial polysilicon material 233 may be formed to have a vertical extent (e.g., in the Z-direction) substantially coextensive with the vertical extent of the first slots 104. The sacrificial polysilicon material 233 may be formed of and include at least one material having an etch selectivity relative to the inner dielectric material 232.

Still referring to FIG. 2N, following formation of the sacrificial polysilicon material 233, the sacrificial polysilicon material 233 may be partially removed (e.g., recessed), so that portions of the sacrificial polysilicon material 233 outside of the recesses formed between separator structures 230 neighboring one another in the Y-direction (e.g., outside the memory cell regions 110) may be removed, while portions of the sacrificial polysilicon material 233 within memory cell regions 110 may remain. Removing the portions of the sacrificial polysilicon material 233 may expose corresponding portions of the inner dielectric material 232, wherein remaining sacrificial polysilicon material 233 may substantially extend across and at least partially cover other portions of the inner dielectric material 232 within the memory cell regions 110.

Referring to FIG. 2O, following the partial removal of the sacrificial polysilicon material 233, exposed portions of the inner dielectric material 232 may be removed from within the horizontal areas of the first slots 104. The inner dielectric material 232 that is covered by the sacrificial polysilicon material 233 (FIG. 2N) may remain in the memory cell regions 110. Removal of portions of the sacrificial polysilicon material 233 as described above may expose surfaces of the separator structures 230 outside the memory cell regions 110 and surfaces of the inner dielectric material 232 within the memory cell regions 110. Remaining portions of the inner dielectric material 232 may individually have a vertical extent in the Z-direction substantially vertically aligned with the sacrificial material 202 of the tiers 204 of the preliminary stack structure 102.

Following removal of portions of the inner dielectric material 232, remaining portions of the sacrificial polysilicon material 233 may be removed (e.g., exhumed). Removal of the portions of the sacrificial polysilicon material 233 may expose portions of the inner dielectric material 232 within the memory cell regions 110.

Following removal of the sacrificial polysilicon material 233, a floating gate material 234 may be formed (e.g., deposited) over exposed surfaces of the inner dielectric material 232 and the separator structures 230 within the horizontal areas of the first slots 104. The floating gate material 234 may substantially extend across and at least partially cover the exposed surfaces of the inner dielectric material 232 and the separator structures 230. The floating gate material 234 may substantially conform to a topography of vertically extending surfaces of the inner dielectric material 232 and the separator structures 230. The floating gate material 234 may be formed to have a vertical extent (e.g., in the Z-direction) substantially coextensive with the vertical extend of the first slots 104. The floating gate material 234 may be formed of and include an electrically conductive material. By way of non-limiting example, the floating gate material 234 may be formed of and include a conductively-doped semiconductor material (e.g., conductively-doped silicon, conductively-doped germanium, conductively-doped silicon germanium), polysilicon, one or more of a metal, such as tungsten, titanium, cobalt, rhodium, ruthenium, nickel, platinum, ruthenium, aluminum, copper, molybdenum, iridium, gold, or combinations thereof, a metal alloy, a metal-containing material (e.g., metal nitrides, metal silicides, metal carbides, metal oxides), titanium nitride (TiN), tantalum nitride (TaN), tungsten nitride (WN), titanium aluminum nitride (TiAlN), iridium oxide (IrOx), ruthenium oxide (RuOx), alloys thereof, or combinations thereof, one or more other electrically conductive materials, or combinations thereof. In some embodiments, the floating gate material 234 comprises polysilicon, such as n-doped polysilicon, p-doped polysilicon, or undoped polysilicon.

Following formation of the floating gate material 234, the floating gate material 234 may be partially removed (e.g., recessed), so that portions of the floating gate material 234 outside of the memory cell regions 110 may be removed, while portions of the floating gate material 234 within memory cell regions 110 may remain. Removing the portions of the floating gate material 234 may expose corresponding portions of the separator structures 230 and the edge of the insulative material 203. Individual remaining portions of the floating gate material 234 may continuously span substantially the horizontal extent in the Y-direction of the inner dielectric material 232 within the memory cell regions 110. Remaining portions of the floating gate material 234 may individually have a vertical extent in the Z-direction substantially vertically aligned with the sacrificial material 202 of the tiers 204 of the preliminary stack structure 102.

Still referring to FIG. 2O, following the partial removal of the floating gate material 234, a tunnel oxide material 235 (e.g., a band engineered tunnel oxide material) may be formed (e.g., deposited) over exposed surfaces of the floating gate material 234, the separator structures 230, and the insulative material 203 of the tiers 204. The tunnel oxide material 235 may be formed to substantially extend across and at least partially cover the exposed surfaces of the floating gate material 234, of the separator structures 230, and of the insulative material 203 within the memory cell regions 110. The tunnel oxide material 235 may be formed to continuously span substantially the vertical extent in the Z-direction of the first slots 104. The tunnel oxide material 235 may be formed of and include a dielectric oxide material (e.g., silicon oxide).

As discussed above with respect to FIG. 2E, it may be desirable to form select gate transistors (e.g., metal-oxide-semiconductor (MOS) select gate transistors) at one or more of the uppermost tiers 204 (e.g., in the Z-direction). To form select gate structures, prior to portions of the tunnel oxide material 235, portions of the floating gate material 234 may be removed, followed by removal of portions of the inner dielectric material 232. Thereafter, tunnel oxide material 235 for the select gate structures may be formed concurrently with the tunnel oxide material 235 for the memory cell regions 110, and then semiconductor material 236 (described in further detail below) for the select gate structures may be formed concurrently with the semiconductor material 236 for the memory cell regions 110. In such embodiments, a gate dielectric stack for a respective select gate structure may include the tunnel oxide material 235; the first slot liner material 214; and a separator structure 230 and the middle dielectric material 231 interposed between the tunnel oxide material 235 and the first slot liner material 214. In additional embodiments, the process flow for the formations of the select gate structures is different. For example, at the processing stage previously described herein with reference to FIG. 2E, recessing the sacrificial material 202 of one or more uppermost tiers 204 may be inhibited (e.g., through formation of an additional liner; doping the sacrificial material 202 of the uppermost tiers 204 with a chemical species, such as carbon, to slow etch rate). Thereafter, the trim and oxidation process described herein may be effectuated, followed by formation of the separator structures 230 (including the middle dielectric material 231). High-K material and the floating gate material 234 may subsequently be removed with the “pocket” otherwise formed through recessing the sacrificial material 202 of the one or more uppermost tiers 204. The tunnel oxide material 235 and the semiconductor material 236 (described in further detail below) for the select gate structures may then respectively be formed concurrently with tunnel oxide material 235 and the semiconductor material 236 for the memory cell regions 110. In such embodiments, a gate dielectric stack for a respective select gate structure may include the tunnel oxide material 235; the liner oxide material 218; and a separator structure 230 and the middle dielectric material 231 interposed between the tunnel oxide material 235 and the liner oxide material 218.

Following formation of the tunnel oxide material 235, semiconductor material 236 may be formed (e.g., deposited) over exposed surfaces of the separator structures 230 and the tunnel oxide material 235 within the horizontal areas of the first slots 104. The semiconductor material 236 may substantially extend across and at least partially cover the exposed surfaces of the separator structures 230 and the tunnel oxide material 235 inside and outside of the memory cell regions 110. The semiconductor material 236 may conform to a topography of vertically extending surfaces of the separator structures 230 and the tunnel oxide material 235. The semiconductor material 236 may be formed to have a vertical extent (e.g., in the Z-direction) substantially vertically aligned with the first slots 104. The semiconductor material 236 may be doped or may be substantially undoped. In some embodiments, the semiconductor material 236 is formed of and includes doped polysilicon, such as relatively lightly N-type doped polysilicon or relatively lightly P-type doped polysilicon.

Following formation of the semiconductor material 236, a back oxide material 237 may be formed (e.g., deposited) over exposed surfaces of the semiconductor material 236 within the horizontal areas of the first slots 104. The back oxide material 237 may substantially extend across and at least partially cover the exposed surfaces of the semiconductor material 236. The back oxide material 237 may conform to a topography of vertically extending surfaces of the semiconductor material 236. The back oxide material 237 may be formed to have a vertical extent (e.g., in the Z-direction) substantially coextensive with the vertical extent of the first slots 104. The back oxide material 237 may be formed of and include a dielectric material (e.g., dielectric oxide material, such as silicon oxide).

Still referring to FIG. 2O, following formation of the back oxide material 237, exposed portions of the back oxide material 237 may be removed (e.g., the back oxide material 237 may be recessed) from the first slots 104. The back oxide material 237 may be removed to such a horizontal extent, in the X-direction, that portions of the semiconductor material 236 not in the memory cell regions 110 are exposed. Other portions of the back oxide material 237 memory cell regions 110 may substantially remain in place after removal of the portions of the back oxide material 237.

Following removal of portions of the back oxide material 237, exposed portions of the semiconductor material 236 may be removed (e.g., the semiconductor material 236 may be recessed) from the first slots 104. In removing the exposed portions of the semiconductor material 236, other portions of the semiconductor material 236 within the memory cell regions 110 may substantially remain. Individual remaining portions of the semiconductor material 236 within the memory cell regions 110 may be discontinuous with respect to other portions of the semiconductor material 236 within other memory cell regions 110. The semiconductor material 236, the middle dielectric material 231, and the back oxide material 237 may have a vertical extent (e.g., in the Z-direction) substantially vertically aligned with the lower base structure material 207, the base sacrificial material 208, the upper base structure material 209, the lower deck 205, and the upper deck 216. The semiconductor material 236, middle dielectric material 231, and back oxide material 237 may individually have an upper boundary at least partially vertically aligned with the top dielectric material 217 and a lower boundary at least partially vertically aligned with the base dielectric material 206 (FIG. 2A). Removing exposed portions of the semiconductor material 236 may form vertical memory string structures 211 within corresponding memory cell regions 110. An individual vertical memory string structure 211 may comprise portions of the middle dielectric material 231, the inner dielectric material 232, the floating gate material 234, the tunnel oxide material 235, and the semiconductor material 236 within the horizontal profile of an individual memory cell region 110. As such, the vertical memory string structures 211 may be positioned at and around the outer horizontal boundaries of the first slots 104.

Referring to FIG. 2P, following formation of the vertical memory string structures 211, an insulative fill material 238 may be formed within horizontal areas of the first slots 104 (FIG. 2O), thereby forming first filled slots 239. The insulative fill material 238 may substantially fill portions of the first slots 104 that remained unfilled by the tunnel oxide material 235, floating gate material 234, inner dielectric material 232, back oxide material 237, semiconductor material 236, or middle dielectric material 231. The insulative fill material 238 may be formed of and include dielectric material (e.g., dielectric oxide material, such as silicon oxide). The insulative fill material 238 may have etch selectivity relative to the top dielectric material 217, the separator structures 230, the back oxide material 237, and the semiconductor material 236.

Following formation of the insulative fill material 238, portions of the insulative fill material 238 overlying an uppermost surface (e.g., in the Z-direction) of the top dielectric material 217 may be removed (e.g., through an abrasive planarization process, such as a CMP process). Removal of the insulative fill material 238 may likewise remove uppermost surfaces (e.g., in the Z-direction) of the top dielectric material 217, the separator structures 230, the back oxide material 237, and/or the semiconductor material 236. An upper surface of the insulative fill material 238 may be substantially coplanar with upper surfaces of the top dielectric material 217, the separator structures 230, the back oxide material 237, and the semiconductor material 236.

Still referring to FIG. 2P, portions of the insulative fill material 238 and the back oxide material 237 within the third slot regions 108 (FIG. 1) may be removed, forming individual third slots. The insulative fill material 238 and the back oxide material 237 may be partially removed by conventional material removal (e.g., photolithography, etching) techniques to pattern voids in the individual third slot regions 108. The third slots may individually have a substantially rectangular horizontal cross-sectional shape spanning substantially the vertical extent (e.g., in the Z-direction) of the top dielectric material 217. The partial removal of the insulative fill material 238 and the back oxide material 237 may expose upper surfaces (e.g., in the Z-direction) of the insulative fill material 238 and the back oxide material 237, such upper surfaces defining lower boundaries (e.g., in the Z-direction) of the third slots. Following the partial removal of the insulative fill material 238 and the back oxide material 237, the top dielectric material 217, the separator structures 230, and the semiconductor material 236 may remain in place. The partial removal of the insulative fill material 238 may expose horizontal-facing surfaces (e.g., in the X- and Y-directions and combinations thereof) of the separator structures 230 and the semiconductor material 236 at elevations substantially vertically aligned in the Z-direction with the top dielectric material 217.

Following formation of the third slots, plug material may be formed within the third slots. The plug material may be formed in contact with upper portions of the semiconductor material 236. The plug material may be formed of and include polysilicon material doped (e.g., lightly doped) with one or more conductivity enhancing species, such as N-type polysilicon (e.g., polysilicon doped with one or more N-type conductivity-enhancing species, such as one or more of arsenic, phosphorous, and antimony). The plug material may contact (e.g., physically contact) the respective semiconductor material 236 of multiple (e.g., a plurality of) horizontally neighboring vertical memory string structures 211. In some embodiments, plug material is formed to contact the semiconductor material 236 of eight (8) vertical memory string structures 211 positioned at and around the outer horizontal boundaries of an individual first slot 104.

Following formation of the plug material, portions thereof overlying an uppermost surface (e.g., in the Z-direction) of the top dielectric material 217 and/or the insulative fill material 238 may be removed (e.g., through an abrasive planarization process, such as a CMP process) to form plug structures 240. Removal of the plug material may likewise remove uppermost surfaces (e.g., in the Z-direction) of the top dielectric material 217 and/or the insulative fill material 238. Upper surfaces of the plug structures may be substantially coplanar with upper surfaces of the top dielectric material 217 and the insulative fill material 238. The plug structures 240 may be employed as drain side contact structures for the vertical memory string structures 211.

Referring to FIG. 2Q, following formation of the plug structures 240, a dielectric cover 241 may be formed to substantially cover and continuously extend across the exposed upper surfaces (e.g., in the Z-direction) of the top dielectric material 217, the semiconductor material 236 (FIG. 2P), the separator structures 230 (FIG. 2P), the insulative fill material 238, and the plug structures 240. The dielectric cover 241 may be formed of and include dielectric oxide material (e.g., silicon oxide).

Following formation of the dielectric cover 241, at least one second slot 242 (e.g., trench, opening, slit) may be formed within the second slot regions 106 (FIG. 1) and may vertically extend (e.g., in the Z-direction) completely through the dielectric cover 241, the top dielectric material 217, the upper deck 216, the lower deck 205, and the upper base structure material 209. Additionally, the second slot 242 may vertically extend at least partially through the base sacrificial material 208. The second slot 242 may be formed by removing portions of the dielectric cover 241, the top dielectric material 217, the preliminary stack structure 102 (including the tiers 204 of insulative material 203 and sacrificial material 202 thereof), the upper base structure material 209, and the base sacrificial material 208. The formation of the second slot 242 may expose a side surface of the base sacrificial material 208.

FIGS. 2R and 2S show enlarged views of a lower portion of the sub-section B (FIG. 2D) of the region A (FIG. 1) of the microelectronic device structure 100 following the processing stage described above with reference to FIG. 2Q. The views of FIGS. 2R and 2S show, without limitation, enlarged views of portions of the base structure 201 and the lower deck 205 of the preliminary stack structure 102. As depicted in FIG. 2R, following formation of the second slots 242 (FIG. 2Q), at least a portion of the base sacrificial material 208 (FIG. 2Q) of the base structure 201 may be removed (e.g., exhumed) by way of the second s slots 242 to form a horizontal recess 243 that extends horizontally (e.g., in the Y-direction) from the second slots 242 to the vertical memory string structures 211 (FIG. 2P). Forming the horizontal recess 243 may expose portions of the tunnel oxide material 235 of individual vertical memory string structures 211 at or around horizontal boundaries of the first filled slots 239.

Referring to FIG. 2S, following removal of the base sacrificial material 208 (FIG. 2Q), exposed portions of the tunnel oxide material 235 (FIG. 2R) at the vertical elevation (e.g., in the Z-direction) of the horizontal recess 243 (FIG. 2R) may be removed to expose lower portions of the semiconductor material 236 to the horizontal recess 243. Semiconductor material 236 of multiple vertical memory string structures 211 may be exposed to an individual horizontal recess 243.

After exposing the semiconductor material 236, the horizontal recesses 243 may be back-filled with lateral contact material 244 by way of the second slot 242. The lateral contact material 244 may have substantially the same material composition as the semiconductor material 236 and/or the lower base structure material 207, or may have a different material composition than the semiconductor material 236 and/or the lower base structure material 207. In some embodiments, the lateral contact material 244 is formed of and includes doped polysilicon, such as relatively heavily N-type doped polysilicon.

The lateral contact material 244 may contact (e.g., physically contact, electrically contact) the semiconductor material 236 of multiple (e.g., a plurality of) horizontally neighboring vertical memory string structures 211 positioned at and around the outer horizontal boundaries of an individual first filled slot 239. In some embodiments, the lateral contact material 244 contacts sixteen (16) vertical memory string structures 211 positioned at and around the outer horizontal boundaries of an individual first filled slot 239. The lateral contact material 244 may be employed as a laterally extending source contact material for the vertical memory string structures 211.

Referring to FIG. 2T, following the formation of the lateral contact material 244, portions of the lateral contact material 244 within the second slot 242 and above elevations (e.g., in the Z-direction) of the base structure 201 may be removed (e.g., by isotropic etching). Thereafter, the microelectronic device structure 100 may be subjected to replacement gate processing to convert the preliminary stack structure 102 (FIG. 2S) into a stack structure 245. The replacement gate processing may at least partially (e.g., substantially) replace the sacrificial material 202 of the tiers 204 of the preliminary stack structure 102 with conductive material 246. As shown in FIG. 2T, the stack structure 245 may include a vertically alternating (e.g., in the Z-direction) sequence of the insulative material 203 and the conductive material 246 arranged in tiers 204′.

Still referring to FIG. 2T, the replacement gate processing employed to form the stack structure 245 may include treating the microelectronic device structure 100 with at least one wet etchant formulated to selectively remove (e.g., exhume) portions of the sacrificial material 202 (FIG. 2S) of the tiers 204 by way of the second slots 242. The wet etchant may be selected to remove the portions of the sacrificial material 202 without substantially removing portions of the insulative material 203 of the tiers 204 of the preliminary stack structure 102 (FIG. 2S), and without substantially removing portions of the base structure 201, the vertical memory string structures 211, the plug structures 240, the top dielectric material 217, the dielectric cover 241, or the insulative fill material 238. In some embodiments wherein the sacrificial material 202 comprises a dielectric nitride material (e.g., SiN_{y}, such as Si₃N₄) and the insulative material 203 comprises a dielectric oxide material (e.g., SiOₓ, such as SiO₂), the sacrificial material 202 of the tiers 204 of the preliminary stack structure 102 may be selectively removed using a wet etchant comprising H₃PO₄.

Following the selective removal of the portions of the sacrificial material 202, an outer dielectric material 247 may be formed over exposed surfaces of the insulative material 203 of the tiers 204, the liner oxide material 218, and the middle dielectric material 231. The outer dielectric material 247 may substantially extend across and at least partially cover the exposed surfaces of the insulative material 203, the liner oxide material 218, and the middle dielectric material 231. The outer dielectric material 247 may conform to a topography of exposed surfaces of the insulative material 203, the liner oxide material 218, and the middle dielectric material 231. The outer dielectric material 247 may be formed to have a vertical extent (e.g., in the Z-direction) that substantially vertically overlaps vertical extents of the upper deck 216 and the lower deck 205. The outer dielectric material 247 may be formed of and include a high-K dielectric material, such as high-K dielectric oxide material (e.g., one or more of HfOₓ, NbOₓ, TiOₓ, AlOₓ, and ZrOₓ).

Following the formation of the outer dielectric material 247, the remaining space in the voids formed by removal of the sacrificial material 202 of the tiers 204 may be substantially filled with the conductive material 246 by way of the second slots 242 to form the stack structure 245 (including the tiers 204′ thereof). The conductive material 246 of the tiers 204′ of the stack structure 245 may be formed of and include one or more of at least one metal, at least one alloy, at least one conductive metal-containing material (e.g., at last one conductive metal nitride, at least one conductive metal silicide, at least one conductive metal carbide, at least one conductive metal oxide), and at least one conductively doped semiconductor material (e.g., conductively doped polysilicon). In some embodiments, the conductive material 246 is formed of and includes W. Optionally, at least one conductive material liner 248 (FIG. 2U) (e.g., at least one insulative liner material, at least one conductive liner material) may be formed around the conductive material 246. The conductive material liner 248 may, for example, be formed of and include one or more of a metal (e.g., titanium, tantalum), an alloy, a metal nitride (e.g., tungsten nitride, titanium nitride, tantalum nitride), and a metal oxide (e.g., aluminum oxide). In some embodiments, the conductive material liner 248 comprises at least one conductive material employed as a seed material for the formation of the conductive material 246. In some embodiments, the conductive material liner 248 comprises titanium nitride (TiNₓ, such as TiN). In further embodiments, the conductive material liner 248 further includes aluminum oxide (AlOₓ, such as Al₂O₃). As a non-limiting example, for each of the tiers 204′ of the stack structure 245, AlOₓ (e.g., Al₂O₃) may be formed directly adjacent the insulative material 203, TiNₓ (e.g., TiN) may be formed directly adjacent the AlOₓ, and W may be formed directly adjacent the TiNₓ. The conductive material 246, the conductive material liner 248, and the outer dielectric material 247 may be horizontally recessed to separate (e.g., isolate) different portions thereof at vertical positions of different tiers 204′ of the stack structure 245 from one another.

FIG. 2U depicts a simplified, partial top-down section view of the microelectronic device structure 100 following the processing stages described above with reference to FIG. 2T. For clarity and case of understanding the drawings and associated description, a section of the microelectronic device structure 100, indicated by region A in FIG. 1, is depicted in FIG. 2U.

Following the formation of the stack structure 245, the second slots 242 may be filled with insulative material (e.g., dielectric oxide material, such as silicon oxide), thereby forming second filled slots 249. The first filled slots 239 individually include one or more vertical memory string structures 211 within memory cell regions 110 at and around the outer horizontal boundaries of the first filled slots 239. Neighboring vertical memory string structures 211 may be separated in the Y-direction by individual separator structures 230. An individual vertical memory string structure 211 comprises the back oxide material 237 inwardly horizontally adjacent (e.g., toward a center of the first filled slot 239 in the X-direction) to the semiconductor material 236, the semiconductor material 236 inwardly horizontally adjacent in the X-direction to the tunnel oxide material 235, the tunnel oxide material 235 inwardly horizontally adjacent in the X-direction to the floating gate material 234, the floating gate material 234 inwardly horizontally adjacent in the X-direction to the inner dielectric material 232, the inner dielectric material 232 inwardly horizontally adjacent in the X-direction to the middle dielectric material 231, the middle dielectric material 231 inwardly horizontally adjacent in the X-direction to the outer dielectric material 247, and the outer dielectric material 247 inwardly horizontally adjacent in the X-direction to material of the stack structure 245. The inner dielectric material 232, middle dielectric material 231, and outer dielectric material 247 located between adjacent separator structures 230 in the Y-direction may jointly form memory storage material 250 (e.g., a charge storage material) of an individual vertical memory string structure 211. In some embodiments, the memory storage material 250 is an inter-polysilicon dielectric (IPD) material.

The microelectronic device structure 100 may include the memory cell regions 110 located at intersections of the vertical memory string structure 211 and conductive material 246 of the tiers 204′. Individual vertical memory string structures 211 may vertically span substantially the entire vertical extent (e.g., in the Z-direction) of the first filled slots 239. The vertical memory string structures 211 may individually comprise multiple transistors. Some of the conductive material 246 may be employed as individual gate electrodes for corresponding transistors of the vertical memory string structures 211. The conductive material 246 or the conductive material liner 248 may be adjacent to (e.g., in direct contact with) portions of the outer dielectric material 247. Some of the conductive material 246 of the tiers 204′ may be employed as access line structures (e.g., word line structures) for the vertical memory string structures 211. One or more of the lowermost tiers 204′ (e.g., in the Z-direction) of the stack structure 245 may be employed as first select gate structures (e.g., select gate source (SGS) structure(s)), and one or more of the uppermost tiers 204′ (e.g., in the Z-direction) may be employed as second select gate structures (e.g., select gate drain (SGD) structure(s)).

The microelectronic device structure 100 may be divided (e.g., segmented, partitioned) into blocks separated from one another (e.g., in the Y-direction) by the second filled slots 249. At least some of the blocks of the microelectronic device structure 100 may horizontally extend substantially in parallel in the X-direction. Individual blocks of the microelectronic device structure 100 may exhibit substantially the same geometric configuration (e.g., substantially the same dimensions and substantially the same shape) as each other of the blocks, or one or more of the blocks may exhibit a different geometric configuration (e.g., one or more different dimensions and/or a different shape) than one or more other of the blocks. In addition, each pair of horizontally neighboring blocks of the microelectronic device structure 100 may be horizontally separated from one another by substantially the same distance (e.g., corresponding to a width in the Y-direction of individual second filled slots 249) as other pairs of horizontally neighboring blocks of the microelectronic device structure 100, or at least one pair of horizontally neighboring blocks of the microelectronic device structure 100, may be horizontally separated from one another by a different distance than that separating at least one other pair of horizontally neighboring blocks of the microelectronic device structure 100. In some embodiments, the blocks of the microelectronic device structure 100 are substantially uniformly (e.g., substantially non-variably, substantially equally, substantially consistently) sized, shaped, and spaced relative to one another. The individual blocks of the microelectronic device structure 100 may be further subdivided into sub-blocks, an individual sub-block being defined by the horizontal profile of a corresponding first filled slot 239 and memory cell regions 110 at and around the outer horizontal boundaries of the first filled slot 239. Thus, a sub-block may include the vertical memory string structures 211 on two (2) opposing (e.g., in the X-direction) sidewalls 212 partially defining a first filled slot 239.

While processing stages described herein with reference to FIGS. 2A through 2U describe the formation of a microelectronic device structure 100 including floating-gate type memory cell configurations. In additional embodiments, the microelectronic device structure 100 may instead be formed to include charge-trap type memory cell configurations. In such embodiments, the processing stages (and associated processing act) described with reference to FIGS. 2A through 2U may be modified as follows. The microelectronic device structure 100 may be subjected to the processing previously described herein with reference to FIGS. 2A through 2D, but at the processing stage of FIG. 2E recessing the sacrificial material 202 of the tiers 204 relative to the relative to the insulative material 203 of the tiers 204 may be omitted (e.g., may not be effectuated). Thereafter, the microelectronic device structure 100 may be subjected to additional processing substantially similar to that previously described with reference to FIGS. 2F through 2M (but in the absence of the “shelves” otherwise formed by recessing the sacrificial material 202 of the tiers 204 relative to the insulative material 203 of the tiers 204). Thereafter, the separator structures 230, a barrier material (e.g., silicon oxide), a storage nitride material (in place of the floating gate material 234 and high-K dielectric material(s)), the tunnel oxide material 235, the semiconductor material 236, and the back oxide material 237 may be formed in sequence using processing acts similar to those previously described herein. A barrier oxide may be formed by deposition or by oxidization of the sacrificial material 202. The back oxide material 237 may then be recessed, followed by recessing of the semiconductor material 236 to effectuate the formation of vertical memory string structures corresponding to the vertical memory string structures 211 previously described herein (but having charge-trap type memory cell configurations rather than floating-gate type memory cell configurations).

Thus, in accordance with embodiments of the disclosure, a method of forming a microelectronic device includes forming a top dielectric material over a preliminary stack structure overlying a base structure, forming a first slot vertically extending through the top dielectric material and the preliminary stack structure and at least partially through the base structure, the first slot partially defined by sidewalls of the preliminary stack structure, the top dielectric material, and the base structure, forming a first mask material over the sidewalls, forming a trim material over the first mask material within the first slot, removing portions of the trim material, removing portions of at least the first mask material after removing the portions of the trim material to form a mask material edge, forming a preliminary separator structure at the mask material edge and vertically extending through the first slot, and forming a vertical memory string structure within the first slot. The preliminary stack structure includes tiers, each tier comprising a first material and an insulative material vertically neighboring the first material. The sidewalls of the preliminary stack structure, the top dielectric material, and the base structure horizontally extend in a first direction. The first mask material horizontally extends inward into the first slot in a second direction orthogonal to the first direction. The mask material edge faces the first direction. The vertical memory string structure is horizontally adjacent to the preliminary separator structure in the first direction.

In accordance with additional embodiments of the disclosure, a microelectronic device includes a stack structure. The stack structure includes tiers and is divided into blocks. Each tier includes a conductive material vertically neighboring an insulative material. The blocks are separated from one another in a first direction and horizontally extending in parallel in a second direction. The second direction is substantially orthogonal to the first direction. At least one of the blocks includes first slots and vertical memory string structures. The first filled slots vertically extend completely through the tiers of the stack structure. The first slots individually have horizontal boundaries partially defined by two sidewalls of the stack structure that horizontally extend in the first direction. The vertical memory string structures are positioned at and around the horizontal boundaries of the first filled slots. The vertical memory string structures are separated in the first direction by separator structures. The vertical memory string structures vertically extend completely through the tiers of the stack structure. The vertical memory string structures include semiconductor material, a tunnel oxide material, a floating gate material, and an inter-polysilicon dielectric (IPD) material. The semiconductor material vertically extends through the stack structure. The tunnel oxide material is horizontally adjacent to the semiconductor material and vertically extends through the stack structure. The floating gate material is horizontally adjacent to the tunnel oxide material and includes portions individually vertically overlapping the conductive material of the tiers of the stack structure. The portions of the floating gate material are vertically separated from one another by the insulative material of the tiers of the stack structure. The IPD material is horizontally adjacent to the floating gate material and includes sections individually vertically overlapping the conductive material of the tiers of the stack structure. The sections of the IPD material are vertically separated from one another by the insulative material of the tiers of the stack structure.

In accordance with yet additional embodiments of the disclosure, a memory device includes a stack structure. The stack structure includes blocks. The blocks extend in parallel in a first horizontal direction. The blocks individually include tiers. Each tier comprises conductive material and insulative material vertically neighboring the conductive material. The blocks individually comprise first filled slots. The first filled slots vertically extend through the tiers. The first filled slots include vertical memory string structures and separator structures. The vertical memory string structures are at and around outer horizontal boundaries of the first filled slots. The vertical memory string structures individually comprise semiconductor material and charge storage material. The semiconductor material vertically extends through the tiers. The charge storage material has individual portions substantially vertically aligned with the conductive material of the tiers of the stack structure and vertically separated from one another by the insulative material of the tiers of the stack structure. The separator structures vertically extend through the tiers. The separator structures are individually horizontally interposed between two of the vertical memory string structures horizontally neighboring one another.

In accordance with further embodiments of the disclosure, a memory device includes a stack structure having blocks extending in parallel in a first horizontal direction and individually including tiers each comprising conductive material and insulative material vertically neighboring the conductive material. The blocks individually include first filled slots vertically extending through the tiers. The first filled slots respectively include separator structures vertically extending through the tiers, semiconductor material horizontally interposed between the separator structures and vertically extending through the tiers, and memory storage material formed along concave shapes defined by the separator structures.

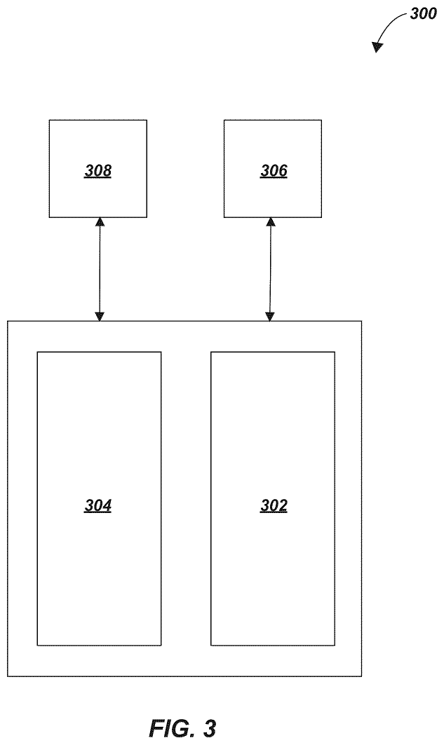

Microelectronic devices structures (e.g., the microelectronic device structure 100 previously described with reference to one or more of FIGS. 2T and 2U) in accordance with embodiments of the disclosure may be used in electronic systems. For example, FIG. 3 is a block diagram of an illustrative electronic system 300 according to embodiments of this disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® tablet, a SURFACE® tablet, an electronic book, a navigation device.

The electronic system 300 includes at least one memory device 302. The memory device 302 may comprise, for example, the microelectronic device structure 100. The electronic system 300 may further include at least one electronic signal processor device 304 (often referred to as a “microprocessor”). The electronic signal processor device 304 may, optionally, include the microelectronic device structure 100 following the processing stages previously described with reference to FIGS. 2T and 2U. While the memory device 302 and the electronic signal processor device 304 are depicted as two separate devices in FIG. 3, in additional embodiments, a single (e.g., only one) memory/processor device having the functionalities of the memory device 302 and the electronic signal processor device 304 may be included in the electronic system 300. In such embodiments, the memory/processor device includes the microelectronic device structure 100 following the processing stages previously described with reference to FIGS. 2T and 2U. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 comprise a single touchscreen device that can be used both to input information to the electronic system 300 and to output visual information to a user. The input device 306 and the output device 308 may communicate electrically with one or more of the memory device 302 and the electronic signal processor device 304.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, devices, and methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

What is claimed is:

1. A method of forming a microelectronic device, comprising:
forming a top dielectric material over a preliminary stack structure overlying a base structure, the preliminary stack structure comprising tiers each comprising a first material and an insulative material vertically neighboring the first material;
forming a first slot vertically extending through the top dielectric material and the preliminary stack structure and at least partially through the base structure, the first slot partially defined by sidewalls of the preliminary stack structure, the top dielectric material, and the base structure horizontally extending in a first direction;
forming a first mask material over the sidewalls and horizontally extending inward into the first slot in a second direction orthogonal to the first direction;
forming a trim material over the first mask material within the first slot;
removing portions of the trim material;
removing portions of at least the first mask material, after removing the portions of the trim material, to form a mask material edge facing the first direction;
forming a preliminary separator structure at the mask material edge and vertically extending through the first slot; and
forming a vertical memory string structure within the first slot and horizontally adjacent to the preliminary separator structure in the first direction.

2. The method of claim 1, further comprising forming a second mask material over exposed surfaces of the first mask material within the first slot, and wherein:
forming a trim material over the first mask material within the first slot comprises forming the trim material over exposed surfaces of the second mask material within the first slot;
removing portions of the trim material comprises removing portions of the trim material to partially expose the second mask material; and
removing portions of at least the first mask material comprises removing portions of the first mask material and the second mask material, the first mask material removed at a first etch rate, and the second mask material removed at a second etch rate slower than the first etch rate.

3. The method of claim 2, wherein the first etch rate is at least approximately two times as fast as the second etch rate.

4. The method of claim 1, further comprising:
forming additional preliminary separator structures within and vertically extending through the first slot, the additional preliminary separator structures formed through trim-etch cycles individually comprising:
removing additional portions of the trim material;
removing additional portions of at least the first mask material to form an additional mask material edge facing the first direction; and
forming one of the additional preliminary separator structures at the additional mask material edge, the one of the additional preliminary separator structures within and vertically extending through the first slot.

5. The method of claim 1, further comprising:
forming a second slot vertically extending through the top dielectric material and the preliminary stack structure and at least partially through the base structure, the second slot having substantially rectangular horizontal cross-sectional shape comprising:
a first boundary horizontally extending in the first direction; and
a second boundary extending in the second direction and longer than the first boundary.

6. The method of claim 5, further comprising replacing the first material of the tiers of the preliminary stack structure with conductive material after forming the vertical memory string structure.

7. The method of claim 6, wherein replacing the first material of the tiers of the preliminary stack structure with the conductive material comprises:
removing the first material of the tiers of the preliminary stack structure by way of the second slot; and
forming the conductive material vertically neighboring the insulative material in each of the tiers.

8. The method of claim 5, further comprising:
forming the base structure to comprise a base sacrificial material vertically interposed between an upper base structure material and a lower base structure material;
forming a tunnel oxide material of the vertical memory string structure in contact with the base sacrificial material of the base structure;
exposing side surfaces of the base sacrificial material by way of the second slot;
at least partially removing the base sacrificial material to form recesses partially exposing the tunnel oxide material;
laterally extending the recesses into exposed portions of the tunnel oxide material to expose semiconductor material of the vertical memory string structure; and
filling the laterally extended recesses with conductively doped semiconductor material.

9. The method of claim 1, wherein forming the vertical memory string structure comprises:
forming a middle dielectric material inwardly horizontally adjacent, in the second direction, the first material of the tiers of the preliminary stack structure;
forming an inner dielectric material inwardly horizontally adjacent, in the second direction, the middle dielectric material;
forming a floating gate material inwardly horizontally adjacent, in the second direction, the inner dielectric material;
forming a tunnel oxide material inwardly horizontally adjacent, in the second direction, the floating gate material; and
forming semiconductor material inwardly horizontally adjacent in the second direction, the tunnel oxide material.

10. The method of claim 9, wherein forming the vertical memory string structure further comprises:
forming a liner oxide material over exposed surfaces of the sidewalls;
forming the middle dielectric material over exposed surfaces of the liner oxide material;
forming a sacrificial polysilicon material over exposed surfaces of the middle dielectric material;
removing portions of the sacrificial polysilicon material outside of boundaries of a memory cell region to expose portions of the inner dielectric material outside of the memory cell region; and
removing the portions of the inner dielectric material outside of the boundaries of the memory cell region.

11. The method of claim 9, wherein forming the semiconductor material comprises forming the semiconductor material over exposed surfaces of the tunnel oxide material and the preliminary separator structure.

12. The method of claim 1, further comprising forming an end region void within a horizontal area of the first slot, the end region void vertically extending through the first slot.

13. The method of claim 12, wherein removing portions of the trim material and removing portions of the first mask material and a second mask material is at least partially effectuated by way of the end region void.

14. The method of claim 1, further comprising forming an insulative fill material within a remainder of the first slot, the insulative fill material filling at least an upper portion of the first slot.

15. The method of claim 14, further comprising:
selectively removing portions of the insulative fill material at a vertical elevation substantially of the top dielectric material to form a third slot having a substantially rectangular horizontal cross-sectional shape, the third slot horizontally spanning in the second direction between the first slot and an additional first slot horizontally neighboring the first slot; and
forming a conductive plug structure within the third slot.

16. A microelectronic device, comprising:
a stack structure comprising tiers each including a conductive material vertically neighboring an insulative material, the stack structure divided into blocks separated from one another in a first direction and horizontally extending in parallel in a second direction substantially orthogonal to the first direction, at least one of the blocks comprising:
first slots vertically extending completely through the tiers of the stack structure and individually having horizontal boundaries partially defined by two sidewalls of the stack structure horizontally extending in the first direction; and
vertical memory string structures positioned at and around the horizontal boundaries of the first slots and separated in the first direction by separator structures, the vertical memory string structures vertically extending completely through the tiers of the stack structure and comprising:
semiconductor material vertically extending through the stack structure;
a tunnel oxide material horizontally adjacent to the semiconductor material and vertically extending through the stack structure;
a floating gate material horizontally adjacent to the tunnel oxide material and comprising portions individually vertically overlapping the conductive material of the tiers of the stack structure, the portions of the floating gate material vertically separated from one another by the insulative material of the tiers of the stack structure; and
an inter-polysilicon dielectric (IPD) material horizontally adjacent to the floating gate material and comprising sections individually vertically overlapping the conductive material of the tiers of the stack structure, the sections of the IPD material vertically separated from one another by the insulative material of the tiers of the stack structure.

17. The microelectronic device of claim 16, wherein the IPD material comprises:
an inner dielectric material;
an outer dielectric material; and
a middle dielectric material interposed between the inner dielectric material and the outer dielectric material, the middle dielectric material having a different material composition than each of the inner dielectric material and the outer dielectric material.

18. The microelectronic device of claim 16, further comprising a base structure vertically underlying the stack structure and comprising a base semiconductor material contacting side surfaces of the semiconductor material of the vertical memory string structures.

19. A memory device, comprising:
a stack structure comprising:
blocks extending in parallel in a first horizontal direction and individually including tiers each comprising conductive material and insulative material vertically neighboring the conductive material, the blocks individually comprising:
first filled slots vertically extending through the tiers and comprising:
vertical memory string structures at and around outer horizontal boundaries of the first filled slots, the vertical memory string structures individually comprising:
semiconductor material vertically extending through the tiers; and
charge storage material comprising individual portions substantially vertically aligned with the conductive material of the tiers of the stack structure and vertically separated from one another by the insulative material of the tiers of the stack structure; and
separator structures vertically extending through the tiers and individually horizontally interposed between two of the vertical memory string structures horizontally neighboring one another.

20. The memory device of claim 19, wherein the vertical memory string structures individually comprise:
a tunnel oxide material horizontally adjacent to the semiconductor material and vertically extending through the stack structure; and
a floating gate material horizontally adjacent to the tunnel oxide material and the charge storage material, the floating gate material comprising individual sections substantially vertically aligned with the conductive material of the tiers of the stack structure and vertically separated from one another by the insulative material of the tiers of the stack structure.

21. A memory device, comprising:
a stack structure comprising:
blocks extending in parallel in a first horizontal direction and individually including tiers each comprising conductive material and insulative material vertically neighboring the conductive material, the blocks individually comprising:
first filled slots vertically extending through the tiers and respectively comprising:
separator structures vertically extending through the tiers;
semiconductor material horizontally interposed between the separator structures and vertically extending through the tiers; and
memory storage material between the conductive material and the semiconductor material.

22. The memory device of claim 21, wherein the memory storage material comprises a charge storage material, and further comprising:
a barrier material between gate electrodes and the charge storage material; and
a tunnel material between the charge storage material and the semiconductor material.

23. The memory device of claim 21, wherein the memory storage material is formed along concave shapes defined by the separator structures.
